(19) United States
(12) Patent Application Publication
(10) Pub. No.: US 2026/0082998 A1
(43) Pub. Date: Mar. 19, 2026

(54) SEMICONDUCTOR DEVICE AND METHOD FOR MANUFACTURING THE SAME

(71) Applicant: Intel Corporation, Santa Clara, CA (US)

(72) Inventors: Chun-Chiang KUO, Kaohsiung city (TW); Derchang KAU, Cupertino, CA (US); Kai Chiang WU, Hsinchu City (TW); Xiaorong XIONG, Chandler, AZ (US); Po-Yao LIN, New Taipei City (TW); Ravindranath Vithal MAHAJAN, Chandler, AZ (US); Jieping ZHANG, Mesa, AZ (US)

(21) Appl. No.: 19/002,826

(22) Filed: Dec. 27, 2024

Related U.S. Application Data
(63) Continuation-in-part of application No. 18/884,172, filed on Sep. 13, 2024.

(51) Int. Cl. H01L 25/16; H01L 21/48; H01L 23/00; H01L 23/15; H01L 23/48; H01L 23/498; H01L 23/538; H10B 80/00; H10D 89/10

(52) U.S. Cl. CPC H10W 90/00; H10W 20/20; H10W 70/093; H10W 70/611; H10W 70/65; H10W 70/692; H10W 90/401; H10B 80/00; H10D 89/10; H10W 72/227; H10W 72/252; H10W 72/255; H10W 90/24; H10W 90/297; H10W 90/722; H10W 90/724

(57) ABSTRACT

A semiconductor device and a method for fabricating a semiconductor are described. The semiconductor device includes two modules, each module including two tiers, each tier including (i) a passive die including through-silicon vias (TSVs) arranged side-by-side laterally with a core die and (ii) bumps coupling the TSVs and an overhang portion of the core die of a second tier to the TSVs the first tier, the first module further including a bottom redistribution layer (RDL) on which the first second tier of the first module is disposed and a top RDL disposed on the second tier of the first module, the bottom RDL coupled to the bumps disposed on the first tier of the first module while the top RDL configured to couple the bumps of the first tier of the second module to the TSVs of the second tier of the first module in a one-to-one manner.

### CROSS-REFERENCE TO RELATED APPLICATIONS

This application is a continuation-in-part of U.S. patent application Ser. No. 18/884,172 filed Sep. 13, 2024, the contents of which are incorporated by reference.

### BACKGROUND

The escalating need for data processing power necessitates the ability to perform more computations in a smaller space while consuming less energy. In traditional two-dimensional (2D) chip designs, enhancing processing capabilities typically requires expanding the chip's size and energy consumption. However, three-dimensional (3D) designs, also known as vertical integration, have become an effective alternative. These 3D packaging structures enhance the number of functions per unit area while maintaining or even reducing energy usage, all within the same or a reduced footprint. Consequently, electronic devices can be packaged more compactly. A 3D integrated circuit (3DIC) is created by stacking various chips or wafers on top of one another within a single enclosure. The individual chips within this enclosure are linked through methods such as through-silicon vias (TSVs) and micro-bumps or through hybrid bonding technologies.

However, as the need for high performance computing grows, so does the number of layers in 3D packaging. For example, the bandwidth and storage capacity demand for computer memory (e.g., high bandwidth memory is anticipated to grow by two to threefold with each new generation. Due to these escalating requirements, the number of memory layers is expected to reach a high of 12 or even extend up to 16 layers (or tiers). However, if a terraced structure includes more than four tiers of core (e.g., memory) dies and passive (e.g., TSV) dies, there are other potential challenges to meet such escalating requirements, for example, the lack of proper bonding between the dies vertically, possibility of die cracking when the stacked structure exceeds four tiers given the current technologies for die thinning and bumping processes, open joins and bridge joints caused by height variations and co-planarity issues of the stacked dies.

Therefore, there is a need for a semiconductor device (e.g., memory unit, logic chip unit, or a combination thereof) with improved 3D stacking packaging and a method for fabricating the same to address the issues and enable stable stacked structures with more than four tiers/layers of core dies including logic dies and/or memory dies.

### BRIEF DESCRIPTION OF THE DRAWINGS

The accompanying drawings serve to provide an understanding of non-limiting aspects. Further non-limiting aspects and many of the intended advantages will become apparent directly from the following detailed description. The elements and structures shown in the drawings are not necessarily shown to scale relative to each other. Like reference numerals refer to like or corresponding elements and structures. Non-limiting aspects described herein will be better understood by one of ordinary skill in the art from the following detailed description and in conjunction with the drawings, in which:

FIG. 1 is a block diagram showing a cross-sectional view of a conventional high bandwidth memory 3D packaging structure;

FIG. 2 is a schematic diagram showing a cross-sectional view of an alternative 3D packaging structure including active dies without through-silicon vias (TSVs) and separate passive dies that contain TSVs;

FIG. 3A is a schematic diagram showing a perspective view of a terraced memory structure with 15 tiers of memory dies and TSV dies arranged side-by-side horizontally;

FIG. 3B shows a block diagram of first four tiers of a broken terraced memory structure;

FIG. 4A shows a schematic diagram illustrating a cross-sectional view of a terraced memory structure with co-planarity issues in active and passive dies;

FIGS. 4B and 4C show schematic diagrams illustrating chip joint defects of the terraced memory structure of FIG. 4A caused by the co-planarity issues;

FIG. 5A shows a schematic diagram illustrating a cross-sectional view of a non-limiting semiconductor device 500 according to various aspects described herein;

FIG. 5B shows a schematic diagram illustrating a cross-sectional view of a non-limiting semiconductor device according to various aspects described herein;

FIG. 6 shows a schematic diagram illustrating a cross-sectional view of another non-limiting semiconductor device according to various aspects described herein;

FIG. 7 shows a schematic diagram illustrating a cross-sectional view of a non-limiting semiconductor device with four modules according to various aspects described herein;

FIG. 8 shows a schematic diagram illustrating respective routing paths of the plurality of core dies in the semiconductor device of FIG. 7 and a layout of the conductive pads of the top RDLs of the semiconductor device of FIG. 7;

FIG. 9 shows a schematic diagram illustrating a cross-sectional view of another non-limiting semiconductor device with four modules according to various aspects described herein;

FIG. 10 shows a schematic diagram illustrating respective routing paths of the plurality of core dies in the semiconductor device of FIG. 9 with a different layout of the conductive pads of the top RDLs of the semiconductor device of FIG. 9;

FIG. 11 shows a flow chart illustrating a method for fabricating a semiconductor device according to various aspects described herein;

FIGS. 12A, 12B and 12C show flow charts illustrating parts of the processes of a step of the method shown in FIG. 11;

FIGS. 13A and 13B show flow charts illustrating parts of the processes of a step of the method shown in FIGS. 12A and 12B;

FIG. 14 shows a cross-sectional view of a module when a known good module step is carried out after the preparation of the module;

FIG. 15A shows a schematic diagram illustrating a non-limiting core die having a first mixed bump design according to various aspects described herein;

FIG. 15B shows a schematic diagram illustrating a cross-sectional view of a non-limiting module with the first mixed bump design according to the various aspects described herein;

FIG. 16A shows a schematic diagram illustrating a non-limiting core die having a second mixed bump design according to various aspects described herein;

FIG. 16B shows a schematic diagram illustrating a cross-sectional view of a non-limiting module with the second mixed bump design according to the various aspects described herein;

FIG. 17 shows a flow chart illustrating a method for fabricating a semiconductor device according to various aspects described herein;

FIG. 18 shows a schematic diagram illustrating a method for fabricating a semiconductor device according to various aspects described herein;

FIG. 19 shows a schematic diagram illustrating another method for fabricating a semiconductor device according to various aspects described herein;

FIG. 20 shows a schematic diagram illustrating a method for fabricating a core die with a first mixed bump design according to various aspects described herein;

FIG. 21 shows a schematic diagram illustrating a method for fabricating a core die 2102 with a second mixed bump design according to various aspects described herein;

FIGS. 22A to 22D show schematic diagrams for a method of fabricating a plurality of core dies according to various aspects described herein;

FIGS. 23A to 23E show schematic diagrams for a method of fabricating a plurality of passive dies, each of which has a plurality of through-silicon vias according to various aspects described herein.

### DETAILED DESCRIPTION

Aspects described below in the context of a method are analogously valid for the respective element, device, apparatus, or system, and vice versa. Furthermore, it will be understood that the aspects described below may be combined, for example, a part of one aspect may be combined with a part of another aspect, and a part of one aspect may be combined with a part of another aspect.

It should be understood that the singular terms “a”, “an”, and “the” include plural references unless context clearly indicates otherwise. Similarly, the word “or” is intended to include “and” unless the context clearly indicates otherwise.

It will be further understood that the terms “comprise” (and any form of comprise, such as “comprises” and “comprising”), “have” (and any form of have, such as “has” and “having”), “include” (and any form of include, such as “includes” and “including”), and “contain” (and any form of contain, such as “contains” and “containing”) are open-ended linking verbs. As a result, a method or device that “comprises,” “has,” “includes” or “contains” one or more steps or elements possesses those one or more steps or elements, but is not limited to possessing only those one or more steps or elements. Likewise, a step of a method or an element of a device that “comprises,” “has,” “includes” or “contains” one or more features possesses those one or more features, but is not limited to possessing only those one or more features. Furthermore, a device or structure that is configured in a certain way is configured in at least that way, but may also be configured in ways that are not listed.

Approximating language, as used herein throughout the specification and claims, may be applied to modify any quantitative representation that could permissibly vary without resulting in a change in the basic function to which it is related. Accordingly, a value modified by a term or terms, such as “about,” “substantially”, is not limited to the precise value specified but within tolerances that are acceptable for operation of the aspect for an application for which it is intended. In some instances, the approximating language may correspond to the precision of an instrument for measuring the value.

The term “exemplary” may be used herein to mean “serving as an example, instance, or illustration”. Any aspect or design described herein as “exemplary” is not necessarily to be construed as preferred or advantageous over other aspects or designs.

The terms “at least one” and “one or more” may be understood to include a numerical quantity greater than or equal to one (e.g., one, two, three, four, [ . . . ], etc.). The term “a plurality” may be understood to include a numerical quantity greater than or equal to two (e.g., two, three, four, five, [ . . . ], etc.). The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of listed elements.

The term “first”, “second”, “third” detailed herein are used to distinguish one element from another similar element and may not necessarily denote order or relative importance, unless otherwise stated. For example, a first transaction data, a second transaction data may be used to distinguish two transactions based on two different foreign currency exchange.

The term “computing device” may be used herein to mean any suitable device and/or system such as, by way of example and not as a limitation, a personal computer, a laptop, a game console, a mobile phone and the like.

As used herein, the term “connect/connected/connection” may refer to a wired or wireless communication link formed between electronic devices that enables data transmission.

The terms “processor” as used herein may be understood as any kind of entity that allows handling data. The data may be handled according to one or more specific functions executed by the processor or embedded controller. Further, a processor or embedded controller as used herein may be understood as any kind of circuit, e.g., any kind of analog or digital circuit. A processor or an embedded controller may thus be or include an analog circuit, digital circuit, mixed-signal circuit, logic circuit, processor, microprocessor, Central Processing Unit (CPU), Graphics Processing Unit (GPU), Digital Signal Processor (DSP), Field Programmable Gate Array (FPGA), integrated circuit, Application Specific Integrated Circuit (ASIC), etc., or any combination thereof. Any other kind of implementation of the respective functions, which will be described below in further detail, may also be understood as a processor, embedded controller, or logic circuit. It is understood that any two (or more) of the processors, embedded controllers, or logic circuits detailed herein may be realized as a single entity with equivalent functionality or the like, and conversely that any single processor, embedded controller, or logic circuit detailed herein may be realized as two (or more) separate entities with equivalent functionality or the like.

The term “memory” detailed herein may be understood to include any suitable type of memory or memory device, e.g., a hard disk drive (HDD), a solid-state drive (SSD), a flash memory, etc.

As mentioned above, three-dimensional (3D) designs, also known as vertical integration, have become an effective alternative to traditional 2D chip designs for enhancing processing capabilities. These 3D packaging structures enhance the number of functions per unit area while maintaining or even reducing energy usage, all within the same or a reduced footprint. Consequently, electronic devices can be packaged more compactly.

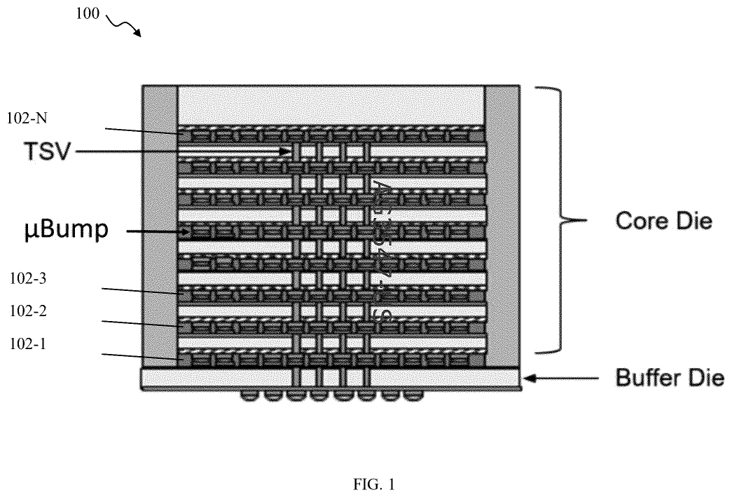

FIG. 1 shows a schematic diagram of a conventional 3D memory device 100. The memory device may be a High Bandwidth Memory (HBM) structure which is a current industrial example of utilizing 3DIC packaging of a memory unit. A 3DIC is created by stacking various chips or wafers on top of one another within a single enclosure. The individual chips (i.e., memory dies or core dies) are stacked vertically and integrated into multiple tiers 102-1, 102-2, 102-3, . . . , 102-N within this enclosure. The individual chips are linked through chip integrated through-silicon vias (TSVs) and micro-bumps (μ-bump) or through hybrid bonding technologies. The 3D vertical stacking method shortens the distances between the layers of dies within the memory unit, enabling quicker data transfer between them while using less power. HBM's exceptional performance is derived from vertically stacking multiple chips, which enables high-performance computing. This is due to benefits like broad input/output interfaces, reduced power requirements, and a smaller physical footprint.

However, the integration of multiple tiers of memory dies stacked vertically introduces significant technical challenges and cost implications. The incorporation of TSVs into each memory die for data transmission requires including the TSV fabrication process into the processing of active dies, such as those used for logic or memory, which are essential; the additional processing can lead to reduced production yields, increased die size and increased manufacturing costs. Additionally, the space required for TSVs on every die can limit circuit design options, amplify production costs and potentially impair device performance. These challenges pose limitations on the scalability of stacked memory technologies, impacting their feasibility for expanding to accommodate more tiers in future designs.

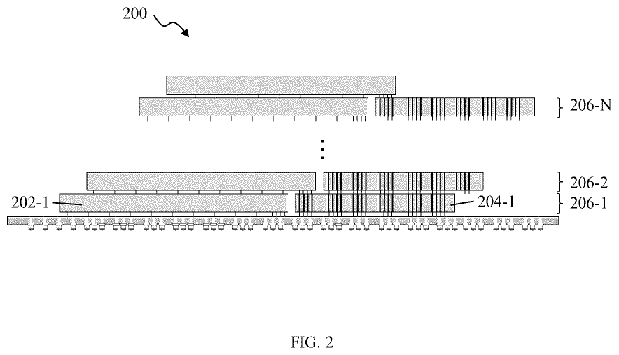

A solution to these challenges includes using an active die without TSVs alongside a separate passive die that contains TSVs for data transfer. FIG. 2 shows a schematic diagram illustrating a cross-sectional view of an alternative 3D packaging structure 200 including active dies without TSVs and separate passive dies that contain TSVs. An active die (e.g., a first active die 202-1) and a passive die (e.g., a first passive die 204-1) are assembled side-by-side horizontally to create a single layer or tier (e.g., a first tier 206-1) while multiple such tiers 206-1, 206-2, . . . , 206-N are stacked vertically into N tiers and terraced (i.e., partially overlaps or laterally offset from each other) to form the alternative 3D packaging structure 200. This may mitigate the issues associated with TSV integration in active dies while benefiting from the advantages of 3D packaging.

However, as the need for high performance computing grows, so does the number of layers in 3D packaging. For example, the bandwidth and storage capacity demand for memory is anticipated to grow by two to threefold with each new generation. Due to these escalating requirements, the number of memory layers is expected to reach a high of 12 or even extend up to 16 layers (or tiers). However, there are other challenges in creating reliable and stable stacked terraced structures with more four tiers of active dies and passive dies to meet such escalating requirements, given the current technologies for die thinning and bumping processes.

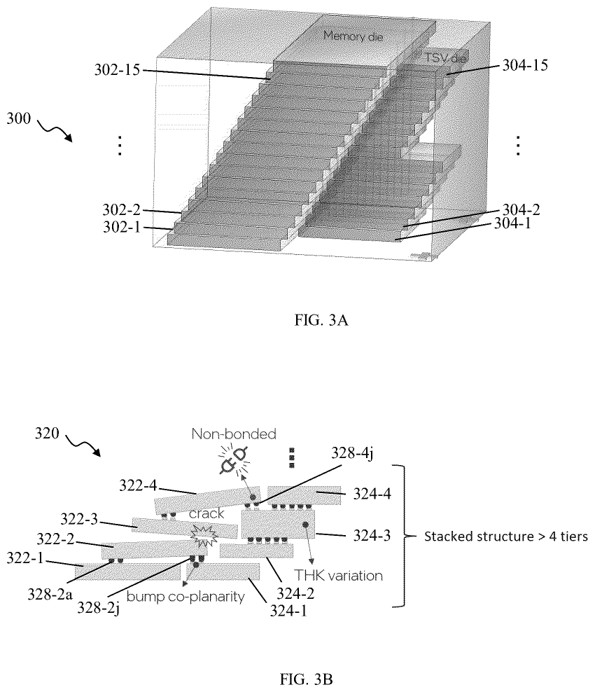

FIG. 3A shows a schematic diagram illustrating a perspective view of a terraced memory structure 300 with 15 tiers of memory dies 302-1, 302-2, . . . , 302-15 and TSV dies 304-1, 304-2, . . . , 304-15 arranged side-by-side horizontally. It is noted that, given the current technologies for die thinning and bumping processes, there could be lack of proper bonding between the dies vertically and possibility of die cracking when the stacked structure exceeds four tiers of active dies and passive dies. FIG. 3B shows a block diagram of first four tiers of a broken terraced memory structure 320 having more than four tiers of active dies and passive dies. When the stacked structure 320 has more than four tiers, there may be a lack of proper bonding, for example, at a bump 328-4j between the fourth active die 322-4 and the third passive die 324-3. There may also be a lack of precision in thickness of die resulting in variations in the die thickness. For example, a third passive die 324-3 is thicker whereas a second passive die 324-2 is thinner than first and fourth passive dies 324-1, 324-4). There may be a lack of precision in bump size resulting in height variations and co-planarity issues. Such height variations and co-planarity issues can accumulate as more tiers are stacked, and also increase the possibility of lacking proper bonding and die cracking. For example, a bump 328-2a connecting first to second active dies 322-1, 322-2 has a different size from that of another bump 328-2j connecting a second active die 322-2 to a first passive die 324-1. This results in the second active die 322-2 slanting upward at one edge, potentially pressing the third active die 322-3 and causing a crack in the second or third active die 322-2, 322-3.

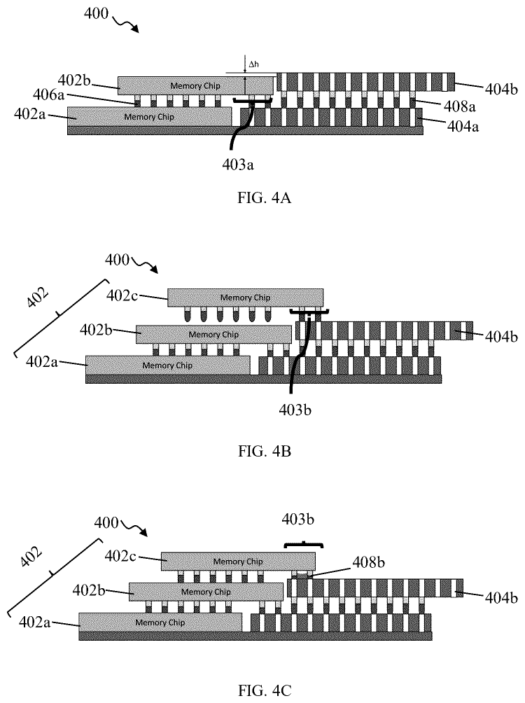

FIG. 4A shows a schematic diagram illustrating a cross-sectional view of a terraced memory structure 400 with co-planarity issues in active and passive dies, and FIGS. 4B and 4C show schematic diagrams illustrating chip joint defects of the memory structure 400 of FIG. 4A caused by the co-planarity issues. A first active die 402a is arranged side by side with a first passive die 404a forming a first tier. A second active die 402b is arranged side by side with a second passive die 404b forming a second tier that is stacked vertically on the first tier. The second active die 402b and the second passive die 404b at the second tier both include respective bottom bumps (e.g., bumps 406a, 408a) protruding away from the second active die 402b and the second passive die 404b, which are configured to connect with the first active die 402a and the first passive die 404a in the first tier. Additionally, the second active die 402b is laterally offset from the first active die 402a forming an overhang portion 403a that overlaps the first passive die 404a. The stack of passive dies 404a, 404b is higher/taller than the active dies stack 402, causing a height variation, denoted as Δh, and a co-planarity issue in the structure 400. Due to the co-planarity issue, when stacking a third active die 402c onto the second tier, only the bottom bumps (e.g., bump 408b) protruding from the overhang portion 403b, which overlaps the second passive die 404b, are connected to the second passive die 404b, while the other portion of the third active die 402c forms open joints, i.e., the bumps of the other portion of the third active die 402c do not form any connection. Alternatively, even when the bumps of the other portion of the third active die 402c are forced to connect with the second active die 402b at the second tier, the pillar of the bumps of the overhang portion 403b of the third active die 402c may be compressed, overflow and form bridge joints which may lead to and short circuit or faulty connection.

Various non-limiting aspects described herein seek to provide an advantageous, structurally stable and reliable semiconductor device (e.g., memory unit, logic chip unit, or a combination thereof). In a first aspect, the semiconductor device may include two or more modules stacked vertically on one another including a base module and a second module stacked vertically on the base module. Each module includes two or more tiers stacked vertically on one another including a base tier and a second tier stacked vertically on the base tier. Each tier includes a passive arranged side-by-side laterally with a core die where the passive die includes a plurality of through-silicon vias (TSVs), and a plurality of bumps disposed on a bottom of the passive die and a bottom of the core die. Additionally, the core die of the second tier is laterally offset from the core die of the base tier, forming an overhang portion overlapping the passive die of the base tier, and where the plurality of bumps of the second tier (i) couple (e.g., connect) the overhang portion of the core die of the second tier and the plurality of TSVs of the passive die of the second tier to the plurality of TSVs of the passive die of the base tier and (ii) couple (e.g., attach) a non-overhang portion of the core die of the second tier to the core die of the base tier. Additionally, the base module also includes a bottom redistribution layer (RDL) on which the base tier of the base module is disposed, the bottom RDL coupled (e.g., connected) to the plurality of bumps of the base tier of the base module, and a top RDL disposed on a top-most tier of the base module (e.g., the second tier stacked on the base tier of the base module if the base module contains only two tiers, or a third tier stacked on the second tier of the base module if the base module contains three tiers), where the second module is disposed on the top RDL of the base module, and the top RDL couples (e.g., connects) the plurality of bumps of the base tier of the top module to a plurality of TSVs of a passive die of the top-most tier of the base module (e.g., the plurality of TSVs of the passive die of the second tier of the base module if the base module contains only two tiers, or a third tier of the base module if the base module contains three tiers) in a one-to-one manner.

In some non-limiting aspects, the semiconductor may include a third module stacked vertically on the second module, the third module also includes a second tier stacked vertically on a first tier, each of the first and second tiers comprises: a passive die arranged side-by-side laterally with a core die, wherein the passive die of the each of the first and second tiers comprises a plurality of TSVs; a plurality of bumps disposed on a bottom of the passive die and a bottom of the core die of the each of the first tier and the second tier. The core die of the second tier of the third module is laterally offset from the core die of the base tier of the third module, forming an overhang portion overlapping the passive die of the base tier of the third module; where the plurality of bumps of the second tier of the third module (i) couple the overhang portion of the core die of the second tier of the third module and the plurality of TSVs of the passive die of the second tier of the third module to the plurality of TSVs of the passive die of the base tier of the third module, and (ii) couple the non-overhang portion of the core die of the second tier of the third module to the core die of the base tier of the third module. The third module is disposed on a (second) top RDL of the second module disposed on a top-most tier of the second module (e.g., the second tier stacked on the base tier of the second module if the second module contains only two tiers, or a third tier stacked on the second tier of the second module if the second module contains three tiers), and the top RDL of the second module couples the plurality of bumps of the base tier of the third module to a plurality of TSVs of the passive die of the tier of the third module; and the top RDL of the base module couples each of the plurality of bumps disposed on the passive die and the core die of the base tier of the third module to a plurality of TSVs of a passive die of the top-most tier of the second module (e.g., the plurality of TSVs of the passive die of the second tier of the second module if the second module contains only two tiers, or a third tier of the second module if the second module contains three tiers) in a one-to-one manner.

In some non-limiting aspects, each or all of the modules (e.g., base module, second module and/or third module) in the semiconductor device may include a third tier stacked vertically on the second tiers, the third tier comprising: a passive die arranged side-by-side laterally with a core die, wherein the passive die of the third tier comprises a plurality of through-silicon vias (TSVs); the core die of the third tier is laterally offset from the core die of the second tier, forming an overhang portion overlapping the passive die of the second tier; and a plurality of bumps disposed on a bottom of the passive die and a bottom of the core die of the third tier; where the plurality of bumps of the third tier couples the overhang portion of the core die of the third tier and the plurality of TSVs of the passive die of the third tier to the plurality of TSVs of the passive die of the second tier and couple the non-overhang portion of the core die of the third tier to the core die of the second tier.

Stated differently, in the first aspect, the base module which serves as a base on which other modules are vertically stacked may contain a bottom redistribution layer with vertical interconnects (e.g., conductive pads and lines) and conductive pads. Each module (e.g., base, middle, top modules) has a top redistribution layer (RDL) (except the top module has no top RDL), and a plurality of core dies and a plurality of passive dies arranged vertically to form a plurality of tiers (e.g., four tiers). A respective passive die of the passive dies is placed side-by-side horizontally with a respective core die of the plurality of core dies. The plurality of core dies are laterally offset from one another, resulting in a stacked and terraced tier structure. Each of the plurality of core dies of a tier (e.g., second tier, third tier, a top-most tier) stacked higher than the respective core die of a lowest tier (e.g., base tier) among the plurality of tiers may form a respective overhang portion overlapping the respective passive die of a lower tier (e.g., a base tier in case of a second tier, or a second tier in case of a third tier).

The plurality of tiers of a module are stacked vertically and coupled through micro-bumps or μ-bumps. Each core die and each passive die include micro-bumps or μ-bumps configured for coupling to a core die or passive die of a lower tier, a top RDL of a lower module, or a bottom RDL of a base module. Each of the plurality of passive dies includes a plurality of first through-silicon vias (TSVs). The modules may be stacked vertically and aligned in a column, where the plurality of core dies and the plurality of passive dies of each module are vertically aligned with those of another module. A core die of the lowest tier of each module is vertically aligned with corresponding core dies of the other modules. Each of the respective pluralities of TSVs of each module is vertically aligned with each of those of the other modules. In one non-limiting example, the respective plurality of TSVs and the respective plurality of bumps of a respective module may be aligned vertically forming a plurality of vertical routing paths that connect the top RDL (e.g., conductive pads on a bottom surface of the top RDL) to an RDL (e.g., conductive pads of an RDL) directly underneath the plurality of tiers (e.g., a top RDL of another module underneath the respective module for modules that are stacked without module bumps or a bottom RDL of the respective module for modules that are stacked with module bumps, or a bottom RDL of the respective module for base modules), and connect the respective overhang portions (e.g., the bumps protruding away from the overhang portions) to the RDL (e.g., different conductive pads of the RDL). The top RDL may further include a routing layer including top conductive lines and pads that connect the plurality of second vertical routing paths to respective first vertical routing paths connected to the top RDL (e.g., conductive pads of the top RDL) among the plurality of first vertical routing paths such that the plurality of dies on the second module stacked vertically on the first module are connected to the bottom RDL of the first module through the vertical routing paths and top RDL between the two modules.

In a second aspect, the semiconductor device may include a bottom RDL, a first passive die arranged side-by-side laterally with a first core die in a base tier on the base RDL; a second passive die arranged side-by-side laterally with a second core die in a second tier stacked vertically on the base tier, wherein the second core die is laterally offset from the first core die, forming an overhang portion overlapping the first passive die; wherein each of the first and second passive dies comprises a plurality of TSVs; and wherein the second tier comprises a plurality of bumps disposed on a bottom of the second passive die and a bottom of the second core die, the plurality of bumps of the second tier comprises a first type of bump configured to couple to the overhang portion of the second core die and the plurality of TSVs of the second passive die to the plurality of TSVs of the first passive die, and a second type of bump configured to couple to a non-overhang portion of the second core die to the first core die. The first type of bump may have a larger diameter, a greater protrusion height and/or a wider pitch than that of the second type of bump.

Stated differently, in the second aspect, the semiconductor device may include a single module which includes a bottom RDL, a plurality of core dies and a plurality of passive dies arranged vertically to form a plurality of tiers (e.g., four tiers). A respective passive die of the passive dies is placed side-by-side horizontally with a respective core die of the plurality of core dies. The plurality of core dies are laterally offset from one another, resulting in a stacked and terraced tier structure. Each of the plurality of core dies stacked of a tier (e.g., second tier, third tier, top-most tier) higher than the respective core die of a lowest tier (e.g., base tier) among the plurality of tiers may form a respective overhang portion overlapping the respective passive die of a lower tier (e.g., a base tier in case of a second tier, or a second tier in case of a third tier).

Each tier (e.g., second tier, third tier, top-most tier) higher than the lowest tier (e.g., base tier) among the plurality of tiers of a module is stacked on a respective lower tier through a plurality of micro-bumps or μ-bumps. The plurality of micro-bumps or μ-bumps of a tier protrude away (e.g., downwards toward a lower tier) from the core die and passive die of the tier. The plurality of μ-bumps including a first type of bump protruding away from the respective passive die and a first portion (e.g., the respective overhang portion) of the respective core die of each tier for coupling (e.g., connecting) to the respective plurality of TSVs of the respective passive die of a lower tier and a second different type of bump protruding from a second portion (e.g., the remaining portion) of the respective core die of each tier for coupling (e.g., connecting) to the respective core die of the lower tier. Each of the plurality of passive dies includes a plurality of first through-silicon vias (TSVs), and the respective pluralities of TSVs of the plurality of passive dies are vertically aligned. In one non-limiting example, the respective plurality of TSVs and the respective plurality of bumps of the module are aligned vertically forming a plurality of vertical routing paths that couple (e.g., connect) respective overhang portions (e.g., the bumps protruding away from the overhang portions) to the bottom RDL (e.g., conductive pads of the bottom RDL).

In a third aspect, the first aspect and the second aspect may be combined. The semiconductor device may include two or more modules stacked vertically on one another including a base module and a second module stacked vertically on the base module. Each module includes two or more tiers stacked vertically on one another including a base tier and a second tier stacked vertically on the base tier. Each tier includes a passive die arranged side-by-side laterally with a core die where the passive die includes a plurality of through-silicon vias (TSVs), and a plurality of bumps disposed on a bottom of the passive die and a bottom of the core die. Additionally, the core die of the second tier is laterally offset from the core die of the base tier, forming an overhang portion overlapping the passive die of the base tier, and where the plurality of bumps of the second tier comprises a first type of bump for coupling the overhang portion of the core die of the second tier and the plurality of TSVs of the passive die of the second tier to the plurality of TSVs of the passive die of the base tier and a second type of bump for coupling an non-overhang portion of the core die of the second tier to the core die of the base tier. Additionally, the base module also includes a bottom redistribution layer (RDL) on which the base tier of the base module is disposed, the bottom RDL coupled to the plurality of bumps of the base tier of the base module, and a top RDL disposed on a top-most tier of the base module (e.g., the second tier stacked on the base tier of the base module if the base module contains only two tiers, or a third tier stacked on the second tier of the base module if the base module contains three tiers), where the second module is disposed on the top RDL of the base module, and the top RDL couples the plurality of bumps of the base tier of the top module to a plurality of TSVs of a passive die of the top-most tier of the base module (e.g., the plurality of TSVs of the passive die of the second tier of the base module if the base module contains only two tiers, or a third tier of the base module if the base module contains three tiers) in a one-to-one manner.

State differently, the base module which serves as a base on which other modules are stacked vertically may contain a bottom redistribution layer with vertical interconnects (e.g., conductive pads and lines) and conductive pads. Each module (e.g., base, middle, top modules) has a top redistribution layer (RDL) (except the top module has no top RDL) and a plurality of core dies and a plurality of passive dies arranged vertically forming a plurality of tiers (e.g., four tiers). A respective passive die of the passive dies is placed side-by-side horizontally with a respective core die of the plurality of core dies forming a respective tier. The plurality of core dies are laterally offset from one another, resulting in a stacked and terraced tier structure. Each of the plurality of core dies of a tier (e.g., a second tier, a third tier, top-most tier) stacked higher than the respective core die of a lowest tier (e.g., base tier) among the plurality of tiers forms a respective overhang portion overlapping the respective passive die of a lower tier (e.g., a base tier in case of a second tier, or a second tier in case of a third tier).

The plurality of tiers are stacked vertically through micro-bumps or μ-bump. For tiers that are higher than the lowest tier among the plurality of tiers of the module, the plurality of μ-bump of each such tier may include a first type of bump protruding from the passive die and away from a first portion (e.g., overhang portion) of the core die of each such tier for connecting to the respective plurality of TSVs of the respective passive die of a lower tier and a second different type of bump protruding from a second portion (e.g., the remaining portion) of the core die of each such tier for connecting to the respective core die of the lower tier.

Each of the plurality of passive dies includes a plurality of first through-silicon vias (TSVs). The modules may be stacked vertically and aligned in a column, where the plurality of core dies and the plurality of passive dies of each module are vertically aligned with those of another module. A core die of the lowest tier of each module is vertically aligned with corresponding core dies of the other modules. Each of the respective pluralities of TSVs of each module is vertically aligned with each of those of the other modules. In one non-limiting example, the respective plurality of TSVs and the respective plurality of bumps of a respective module may be aligned vertically forming a plurality of vertical routing paths that connect the top RDL (e.g., conductive pads on a bottom surface of the top RDL) to an RDL (e.g., conductive pads of an RDL) directly underneath the plurality of tiers (e.g., a top RDL of another module underneath the respective module for modules that are stacked without module bumps or a bottom RDL of the respective module for modules that are stacked with module bumps, or a bottom RDL of the respective module for base modules), and connect the respective overhang portions (e.g., the bumps protruding away from the overhang portions) to the RDL (e.g., different conductive pads of the RDL). The top RDL further includes top conductive lines and pads that connect the plurality of second vertical routing paths to respective first vertical routing paths connected to the top RDL (e.g., conductive pads of the top RDL) among the plurality of first vertical routing paths such that the plurality of dies on the second module stacked vertically on the first module are connected to the bottom RDL of the first module through the vertical routing paths and top RDL between the two modules.

As used herein, the term “semiconductor device” may refer to a component such as a memory unit or a logic chip unit, or a combination of both in computing systems, responsible for storing and processing digital data, respectively. In the context of a memory unit, it may play a pivotal role in facilitating rapid access to information during computing tasks, bridging the gap between processing units and long-term storage devices. Memory units may encompass both volatile types, such as RAM, which offer fast access speeds but require continuous power to maintain data, and non-volatile types like read-only memory (ROM) and flash memory, which retain data even without power. The memory unit may include a high bandwidth memory unit in advanced computing systems. In the context of a logic chip unit, it may be responsible for executing instructions, performing logical operations and data manipulation within the systems. These units typically serve as the core processing such as central processing units (CPUs), graphics processing units (GPUs), or application-specific integrated circuits (ASICs). A semiconductor device may include multiple logic chips and memory units working in tandem to process and execute complex algorithms efficiently.

In various aspect described herein, the term “couple” may where applicable mean electrically connect or electrically couple, and the phrase “a component couples to another component” means a component are electrically connected, coupled or linked to the another component, for example, through electrical connections such as a wire, a pad, a metal line, a solder, a conductor such that electricity or electrical signals can flow between the two components. The term “couple” where applicable may mean physically mounted, fix or adhere, and the phrase “a component couples to another component” means the component are mounted, fixed or adhered to the another component such that the two components stay in a fixed position relative to each other.

The following paragraphs describe an improved 3D stacking package structure of a semiconductor device in accordance with the first aspect.

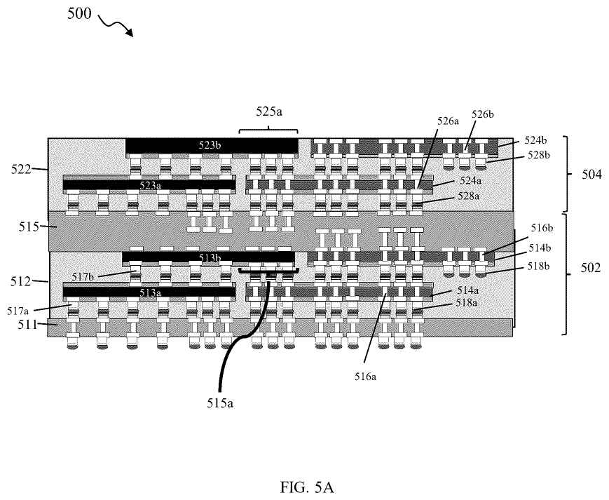

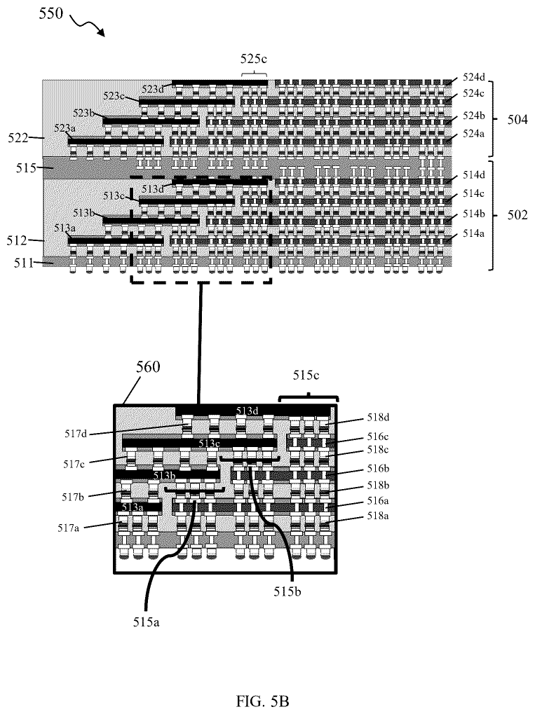

FIG. 5A shows a schematic diagram illustrating a cross-sectional view of a non-limiting semiconductor device 500 according to various aspects described herein. The semiconductor device 500 may include two modules stacked vertically on one another, e.g., aligned in a column: a base module 502 and a second module 504. Each module includes two tiers stacked vertically on one another: a base tier and a second tier. Each of the base tier and the second tier of a module includes a passive die arranged side-by-side laterally with a core die (e.g., passive die 514a with core die 513a, passive die 514b with core die 513b, passive die 524a with core die 523a, passive die 524b with core die 523b), the passive die including a plurality of TSVs (e.g., TSVs 516a, 516b, 526a, 526b), and a plurality of bumps (e.g., bumps 518a, 518b, 528a, 528b) disposed on a bottom of the passive die and a bottom of the core die. The core die (e.g., core die 513b, 523b) of the second tier is laterally offset from the core die of the base tier, forming an overhang portion (e.g., overhang portions 515a, 525a) overlapping the passive die (e.g., passive die 514a, 524a) of the base tier. The plurality of bumps of the second tier (i) connect the overhang portion of the core die 513b, 523b of the second tier and the plurality of TSVs of the passive die 514b, 524b of the second tier to the plurality of TSVs of the passive die 514a, 524a of the base tier and (ii) attach the non-overhang portion of the core die 513b, 523b of the second tier (e.g., a portion of the core die 513b, 523b of the second tier other than the overhang portion) to the core die 513a, 523a of the base tier. The base module 502 further includes a bottom redistribution layer (RDL) 511 on which the base tier of the base module 502 are disposed and a top RDL 515 disposed on a top-most tier (in this non-limiting example shown in FIG. 5A, the second tier) of the base module 502. The bottom RDL 511 is connected to the plurality of bumps of the base tier of the base module 502. The top module 504 is disposed on the top RDL 515 of the base module 502 and the top RDL 515 connects the plurality of bumps (e.g., bump 528a) of the base tier of the top module 504 to a plurality of TSVs of a top-most tier (in this non-limiting example illustrated in FIG. 5A, the plurality of TSVs (e.g., TSV 516b) of the second tier) of the base module 502. That is, the top RDL 515 may connect each of the plurality of bumps of the base tier of the top module 504 to one of the plurality of TSVs of the passive die 514d of the second tier of the base module 502.

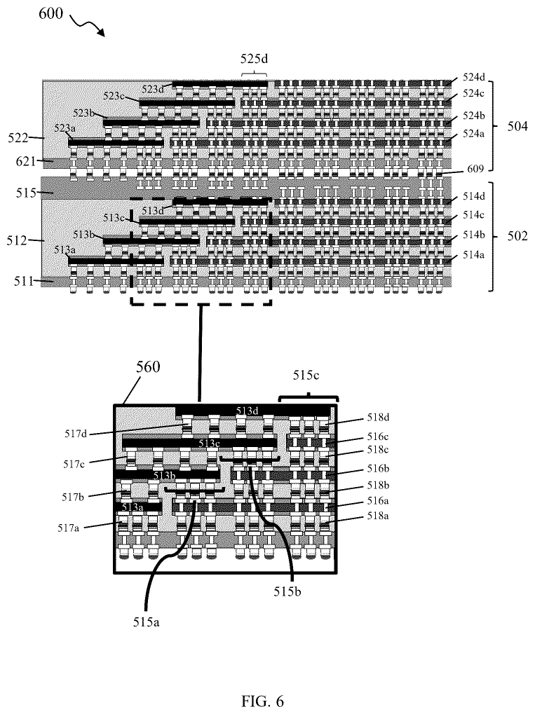

As mentioned earlier, the semiconductor may include more than two tiers within each module. FIG. 5B shows a schematic diagram illustrating a cross-sectional view of a non-limiting semiconductor device 550 according to various aspects described herein. Inset 560 of FIG. 5B shows an enlarged portion of the semiconductor device 550. For purpose of brevity and to avoid unnecessary repetition, components that perform the same or equivalent functions across FIGS. 5A and 5B are designated using the same reference numerals. The description of components bearing the same reference numerals, as detailed in connection with FIG. 5A, may be omitted or may not be repeated in detail in connection with FIG. 5B. However, where applicable, additional details, specific differences, or unique aspects relevant to the particular component in FIG. 6 will be described and highlighted as follows. The semiconductor device 550 may include two modules stacked vertically on one another and aligned in a column: a first module (e.g., base module) 502 and a second module (e.g., top module) 504. Each module includes four tiers stacked vertically on one another: a base tier, a second tier, a third tier and a fourth (top-most) tier. Each module 502, 504 of the semiconductor device 550 may be similar to the semiconductor device 500 shown in FIG. 5A, but further include a third tier stacked vertically on the second tier and a fourth tier stacked vertically on the third tier. Each of the third tier and fourth tier may include a passive die arranged side-by-side laterally with a core die, the passive die including a plurality of TSVs (e.g., TSVs 516c,516d). The core die 513c, 523c of the third tier is laterally offset from the core die 513b, 523b of the second tier, forming an overhang portion (e.g., overhang portion 515b) overlapping the passive die 514b, 524b of the second tier. The core die 513d, 523d of the fourth tier is laterally offset from the core die 513c, 523c of the third tier, also forming overhang portion (e.g., overhang portion 515c, 525c) overlapping the passive die 514c, 524c of the third tier.

In particular, the first module 502 may include a (first) bottom redistribution layer (RDL) 511, a first insulation layer 512 on the bottom RDL 511, a plurality of first core dies (e.g., first core dies 513a, 513b, 513c, 513d) and a plurality of first passive dies (e.g., first passive dies 514a, 514b, 514c, 514d arranged vertically into a plurality of first tiers within the first insulation layer 512 on the bottom RDL, and a top RDL 515. Each of the plurality of first tiers includes a respective first passive die of the plurality of first passive dies placed side-by-side horizontally with a respective first core die of the plurality of first core dies (e.g., first core die 513a with first passive die 514a). The plurality of first core dies are laterally offset from each other, each of the plurality of first core dies (e.g., first core dies 513b, 513c, 513d) stacked higher than the respective first core die (e.g., first core die 513a) of a lowest first tier among the plurality of first tiers forms a respective first overhang portion (e.g., first overhang portions 515a, 515b, 515c) overlapping the respective first passive die (e.g., passive dies 514a, 514b, 514c) of the lower first tier.

Each of the plurality of first passive dies includes a plurality of first through-silicon vias (TSVs) (e.g., TSVs 516a, 516b, 516c in first passive dies 514a, 514b, 514c, respectively). Each first tier, more particularly, the respective first core die and the respective first passive die of each first tier, further includes a respective plurality of first bumps (e.g., first bumps 517a, 517b, 517c, 517d of first core dies 513a, 513b, 513c, 513d and first bumps 518a, 518b, 518c, 518d of first passive dies 514a, 514b, 514c, 514d, respectively) protruding away from the each first tier, and the plurality of first tiers are stacked vertically on each other through such respective pluralities of first bumps.

In this non-limiting example, the second module 504 is stacked vertically on the first module 502 without module bumps, and may include a second insulation layer 522 on the top RDL 515 of the first module, a plurality of second core dies (e.g., second core dies 523a, 523b, 523c, 523d) and a plurality of second passive dies (e.g., second passive dies 524a, 524b, 524c, 524d arranged vertically into a plurality of second tiers within the second insulation layer 522 on the top RDL 515 of the first module 502.

Similar to the first module 502, each of the plurality of second tiers includes a respective second passive die of the plurality of second passive dies placed side-by-side horizontally with a respective second core die of the plurality of second core dies (e.g., second core die 523a with second passive die 524a). The plurality of second core dies are laterally offset from each other, each of the plurality of second core dies (e.g., second core dies 523b, 523c, 523d) stacked higher than the respective second core die (e.g., second core die 523a) of a lowest second tier among the plurality of second tiers forms a respective second overhang portion (e.g., second overhang portion 515d) overlapping the respective second passive die (e.g., passive dies 524a, 524b, 524c) of the lower second tier.

Each of the plurality of second passive dies includes a plurality of second TSVs. Each second tier, more particularly, the respective second core die and the respective second passive die of each second tier, further includes a respective plurality of second bumps protruding away from each second tier, and the plurality of second tiers are stacked vertically on each other through such respective pluralities of second bumps.

According to various aspects described herein, the first module 502 and the second module 504 are aligned in a column where the plurality of first core dies and the plurality of first passive dies and the plurality of second core dies and the plurality of second passive dies are vertically aligned so that a first core die (e.g., 513a) of a lowest first tier and a second core die (e.g., second core die 523a) of a lowest second tier are vertically aligned and each of the respective pluralities of first through-silicon vias (TSVs) of the first module 502 and each of the respective pluralities of second TSVs of the second module 504 are vertically aligned respectively. For example, the respective pluralities of the first TSVs and the respective pluralities of first bumps may be aligned vertically forming a plurality of first vertical routing paths, the plurality of first vertical routing paths respectively connecting the top RDL (e.g., a first plurality of top conductive pads on a bottom surface of the top RDL 515) to the bottom RDL 511 (e.g., a first plurality of bottom conductive pads of bottom RDL 511) and connecting the respective first bumps (e.g., first bump 518d of first core die 513d) of the respective first overhang portions to the bottom RDL 511 (e.g., a second plurality of the bottom conductive pads). The lowest first core die 513a may be connected to the bottom RDL 511 through its respective plurality of first bumps, and the plurality of first vertical routing paths may also include such first vertical routing path connecting the lowest first core die 513a to the bottom RDL 511.

The respective pluralities of the second TSVs and the respective pluralities of second bumps may also be aligned vertically forming a plurality of second vertical routing paths, the plurality of second vertical routing paths through the second insulation layer 522 respectively connecting the respective second bumps of the pluralities of second bumps protruding away from the respective second overhang portions to an RDL directly underneath the plurality of second core dies, in this case, the top RDL 515 (e.g., a second plurality of conductive pads on a top surface of the top RDL 515), and connecting a second top RDL of the second module 504 (if any) also to the top RDL 515 (e.g., a third plurality of conductive pads on a top surface of the top RDL 515). The lowest second core die 523a may be connected to the top RDL 515 through its respective plurality of second bumps, and the plurality of second vertical routing paths may also include such second vertical routing path connecting the lowest second core die 523a to the top RDL 515.

The top RDL 515 may further include a routing layer with respective conductive lines connecting the first plurality of conductive pads at the bottom surface and the second (and third, if any) plurality of conductive pads at the top surface to connect the plurality of second vertical routing paths to respective first routing paths that are connected to the first plurality of top conductive pads among the plurality of first vertical routing paths such that the plurality of first core dies are all connected to the bottom RDL 511 through respective first vertical routing paths while the plurality of second core dies are all also connected to the bottom RDL 511 through respective first and second vertical routing paths and the top RDL 515 between the two modules 502, 504.

FIG. 6 shows a schematic diagram illustrating a cross-sectional view of another non-limiting semiconductor device 600 according to various aspects described herein. Such semiconductor device 600 may be fabricated through different fabrication processes. The semiconductor device 600 may include similar components with identical functions as those of the semiconductor device 500, 550 of FIGS. 5A and 5B, except that there is a bottom RDL and module μ-bumps (hereinafter referred to as module bumps) (e.g., module bump 609) on each higher module (e.g., second module 504) that is stacked vertically on a lower module (e.g., first module 502) for connecting the higher module to the lower module. For purpose of brevity and to avoid unnecessary repetition, components that perform the same or equivalent functions across FIGS. 5A, 5B and 6 are designated using the same reference numerals. The description of components bearing the same reference numerals, as detailed in connection with FIGS. 5A and 5B, may be omitted or may not be repeated in detail in connection with FIG. 6. However, where applicable, additional details, specific differences, or unique aspects relevant to the particular component in FIG. 6 will be described and highlighted as follows.

The second module may further include a second bottom RDL 621 and the plurality of second core dies and the plurality of second passive dies are arranged vertically on the second bottom RDL 621. The second bottom RDL 621 may include a plurality of module bumps protruding away from the second bottom RDL 621 and vertical interconnects (e.g., conductive lines and pads) respectively connecting the plurality of module bumps to the plurality of second vertical routing paths such that the plurality of second vertical routing paths are connected to the respective first vertical routing paths connected to the top RDL further through the plurality of module bumps.

For purposes of avoiding clutter in the drawings, only some of the bumps are labelled in FIGS. 5 and 6. Additionally, to avoid further clutter, each bump shown may represent a bump of a set of one or more bumps. Each die may include M interface ports (M being an integer >=1) (e.g., 1028 interface ports). For example, the first core die 513b may include M interface ports. In such case, the bumps for connecting to the first overhang portion 515b of the first core die 513b may be one bump of a set of M bumps for connecting to the M interface ports of the first core die 513b, and the other bumps of the set are not shown.

As used herein, the term “core die” may refer to a logic die or a memory die. For example, a logic die may be included in a logic chip unit in the context of a CPU chip unit or module that handles primary processing tasks or contains the main processing units (cores) or A memory die may be included in a memory chip unit containing the bulk of the memory cells and basic control circuits in the context of a DRAM memory unit or module. In the context of various aspects described herein, the core die may be used interchangeably with “active die”, and refer to a die or chiplet engaged in active operations including reading, writing or processing data.

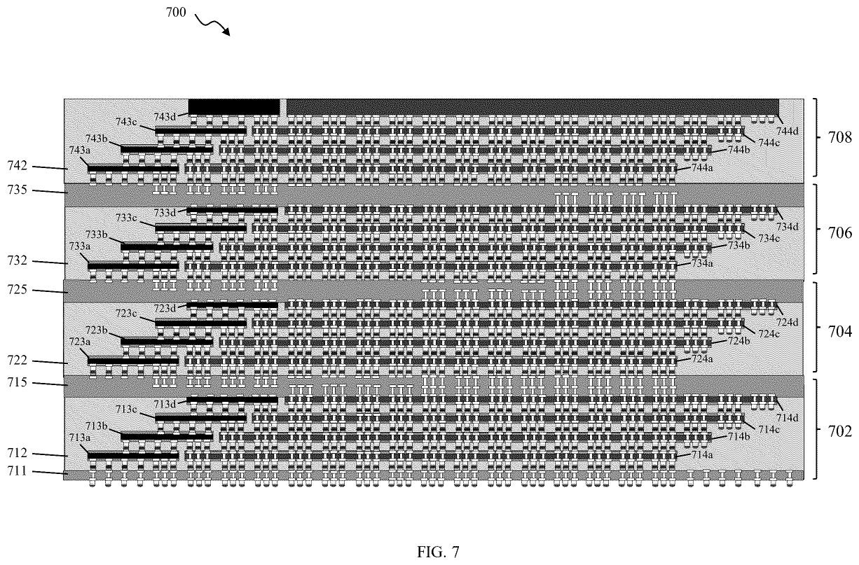

As mentioned earlier, the semiconductor may include more than two modules, a third module stacked vertically on a second module and a fourth (top) module stacked vertically on the third module. FIG. 7 shows a schematic diagram illustrating a cross-sectional view of a non-limiting semiconductor device 700 with four modules according to various aspects described herein.

The semiconductor device 700 may be similar to the semiconductor device 550 shown in FIG. 5BA, but further include a third module 706 (e.g., middle+1 module) stacked vertically on the second module 704 (e.g., middle module) and a fourth module 708 (e.g., top-most module) stacked vertically on the third module 706. Each module includes four tiers stacked vertically on one another: a base tier, a second tier stacked vertically on the base tier, a third tier stacked vertically on the second tier and a fourth tier stacked vertically on the third tier. Each tier of the third module 706 and the fourth module 708 may include a passive die arranged side-by-side laterally with a core die, the passive die including a plurality of TSVs.

Within each module, the core die of the second tier is laterally offset from the core die of the base tier, forming a first overhang portion overlapping the passive die of the base tier. The core die of the third tier is laterally offset from the core die of the second tier, forming a second overhang portion overlapping the passive die of the second tier. The core die of the fourth tier is laterally offset from the core die of the third tier, forming a third overhang portion overlapping the passive die of the third tier. The base module 702 further includes a bottom RDL 711 on which the base tier of the base module 502 is disposed and a top RDL 715 disposed on a top-most tier (in this non-limiting example, the fourth tier) of the base module 702. The bottom RDL 711 is connected to the plurality of bumps of the base tier of the base module 702. The second module 704 is disposed on the top RDL 715 of the base module 702 and the top RDL 715 connects the plurality of bumps of the base tier of the second module 704 to the plurality of TSVs of the passive die 714d of the top-most tier of the base module 702 in a one-to-one manner. Similarly, the second and third modules 704, 706 also include top RDLs 725, 735 disposed on the top-most tier 723d, 733d of the second and third modules, respectively. The third module 706 is disposed on the top RDL 725 of the second 704 and the top RDL 725 of the second module 704 connects the plurality of bumps disposed on the passive die 734a and the core die 733a of the base tier of the third module 706 to the plurality of TSVs of the passive die 724d of the top-most tier of the second module 704 in a one-to-one manner. The top module 708 is disposed on the top RDL 735 of the third module 706 and the top RDL 735 of the third module 706 connects the plurality of bumps disposed on the passive die 744a and the core die 743a of the base tier of the fourth module 708 to the plurality of TSVs of the passive die 734d of the top-most tier of the third module 706 in a one-to-one manner.

In particular, each module may include an insulation layer (e.g., first insulation layer 712, second insulation layer 722, third insulation layer 732, fourth insulation layer 742) and a respective plurality of core dies (e.g., first core dies 713a, 713b, 713c, 713d, second core dies 723a, 723b, 723c, 723d, third core dies 733a, 733b, 733c, 733d, fourth dies 743a, 743b, 743c, 743d and a plurality of first passive dies (e.g., first passive dies 714a, 714b, 714c, 714d, second passive dies 724a, 724b, 724c, 724d, third passive dies 734a, 734b, 734c, 734d, first passive dies 744a, 744b, 744c, 744d) arranged vertically into a plurality of first tiers within the insulation layer. The plurality of dies of each module are laterally offset from each other. Due to the vertical stacking and lateral offsets, each core die of the plurality of core dies stacked higher than the respective core die of a lowest tier among the plurality of tiers within each module forms a respective overhang portion overlapping the respective passive die of a lower tier. The first module 702 may further include a (first) bottom RDL 711 on which the plurality of first core dies is attached and a (first) top RDL 715 on the first insulation layer 712.

Each of the plurality of passive dies in each module includes a plurality of through-silicon vias (TSVs) (e.g., first TSVs in the first module, second TSVs in the second module, third TSVs in the third module. Each first tier, more particularly, the respective core die and the respective passive die of each tier, further includes a respective plurality of bumps protruding away from the each first tier, and the plurality of tiers are stacked vertically on each other through such respective pluralities of bumps.

In this non-limiting example, the modules are stacked vertically on each other without module bumps between them. The second module 704 is stacked vertically on the first module 702. The third module 706 is stacked vertically on the second module 704. The second module 704 and the third module 706 are both middle modules thus they may share similar or identical components (except the layout and design of their top RDL 725, 735). The plurality of second core dies is stacked vertically within the second insulation layer 722 on the top RDL 715. The second module 704 further includes a second top RDL 725 on the second insulation layer 722. The plurality of third core dies is attached vertically within the third insulation layer 732 on the second top RDL 725. The third module 706 further includes a third top RDL 735 (e.g., a top RDL) on the third insulation layer 732. The plurality of fourth dies is stacked vertically within the fourth insulation layer 742 on the third top RDL 735. The height of such unit module (e.g., first module) may be equal to or less than 200 μm excluding module bumps.

According to various aspects described herein, the modules 702, 704, 706, 708 may be stacked vertically and aligned in a column, where the plurality of core dies and the plurality of passive dies of each module are vertically aligned with those of another module. A core die (e.g., first core die 713a, second core die 723a, third core die 733a, fourth core die 744a) of the lowest tier among the plurality of tiers of each module is vertically aligned with corresponding core dies (e.g., first core die 713a, second core die 723a, third core die 733a, fourth core die 744a) of the other modules. Each of the respective pluralities of TSVs of each module is vertically aligned with each of those of the other modules. In one aspect, the respective pluralities of TSVs and the respective pluralities of bumps of each module may be aligned vertically forming a plurality of vertical routing paths, the plurality of vertical routing paths respectively connecting the top RDL (if any) through the insulation layer to an RDL directly underneath the plurality of tiers of that module. The plurality of vertical routing paths may also include routing paths that connect the respective bumps of the respective overhang portions to that RDL (e.g., different bottom conductive pads of the RDL). The lowest core die of the plurality of core dies in each module may also be connected to the same RDL through its respective plurality of bumps, and the plurality of vertical routing paths may also include such vertical routing path connecting the lowest core die to that RDL. Additionally, each top RDL between two modules stacked vertically on each other may further include respective conductive pads facing the two modules and connected to vertical routing paths of the two modules and respective conductive lines for connecting the respective conductive pads such that the vertical routing paths of one module are respectively connected to the vertical routing paths of the other module.

For example, the first module 702 and the second module 704 may be aligned in a column, wherein the plurality of first core dies and the plurality of first passive dies of the first module 702 and the plurality of second core dies and the plurality of second passive dies of the second module 704 are vertically aligned so that a first core die (e.g., first core die 713a) of a lowest first tier among the plurality of first tiers and a second core die (e.g., second core die 723a) of a lowest second tier among the plurality of second tiers are vertically aligned, and wherein each of the respective pluralities of first through-silicon vias (TSVs) of the first module 702 and each of the respective pluralities of second TSVs of the second module 704 are vertically aligned respectively. With that, the respective pluralities of first TSVs and the respective pluralities of first bumps of the first module 702 may be aligned vertically forming a plurality of first vertical routing paths, the plurality of first vertical routing paths respectively connecting the top RDL 715 (e.g., conductive pads at a bottom surface of the top RDL 715) through the first insulation layer 712 to the bottom RDL 711 (e.g., conductive pads of the bottom RDL 711). The plurality of first vertical routing paths also includes routing paths that connect the respective first bumps of the respective first overhang portions of the plurality of first core dies to the bottom RDL 711 (e.g., different bottom conductive pads of the bottom RDL 711). The lowest first core die 713a of the plurality of first core dies in the first module 702 may also be connected to the bottom RDL (e.g., yet other bottom conductive pads of the bottom RDL 711) through its respective plurality of first bumps, and the plurality of first vertical routing paths may also include such first vertical routing path connecting the lowest first core die 713a to the bottom RDL 711.

The second module 704 and third module 706 may also be aligned in the column, wherein the plurality of second core dies and the plurality of second passive dies of the second module 704 and the plurality of third core dies and the plurality of third passive dies of the third module 706 are vertically aligned so that the second core die (e.g., second core die 723a) of the lowest second tier among the plurality of second tiers and a third core die (e.g., third core die 733a) of a lowest third tier among the plurality of third tiers are vertically aligned, and wherein each of the respective pluralities of second TSVs of the second module 704 and each of the respective pluralities of third TSVs of the third module 706 are vertically aligned respectively. With that, the respective pluralities of second TSVs and the respective pluralities of second bumps of the second module 704 may be aligned vertically forming a plurality of second vertical routing paths, the plurality of second vertical routing paths respectively connecting the second top RDL 725 (e.g., conductive pads on a bottom surface of the second top RDL 725) through the second insulation layer 722 to the top RDL 715 (e.g., conductive pads on a top surface of the top RDL 715) of the first module 702. The plurality of second vertical routing paths also includes routing paths that connect the respective second bumps of the respective second overhang portions of the plurality of second core dies to the top RDL 715 (e.g., other conductive pads on a top surface of the top RDL 715) of the first module. The lowest second core die 723a of the plurality of second core dies in the second module 704 may also be connected to the top RDL 715 (e.g., yet other bottom conductive pads on a top surface of the top RDL 715) of the first module through its respective plurality of second bumps, and the plurality of second vertical routing paths may also include such second vertical routing path connecting the lowest second core die 723a to the top RDL 715.

Similarly, the third module 706 and fourth module 708 may also be aligned in the column, wherein the plurality of third core dies and the plurality of third passive dies of the third module 706, and the plurality of fourth core dies and the plurality of fourth passive dies of the fourth module 708 are vertically aligned so that the third core die (e.g., third core die 733a) of the lowest third tier among the plurality of third tiers and a fourth core die (e.g., fourth core die 743a) of a lowest fourth tier among the plurality of fourth tiers are vertically aligned, and wherein each of the respective pluralities of second TSVs of the second module 704 and each of the respective pluralities of third TSVs of the third module 706 are vertically aligned respectively. With that, the respective pluralities of third TSVs and the respective pluralities of third bumps of the third module 706 may be aligned vertically forming a plurality of third vertical routing paths, the plurality of third vertical routing paths respectively connecting the third top RDL 735 (e.g., conductive pads on a bottom surface of the third top RDL 735) through the third insulation layer 732 to the top second RDL 725 (e.g., conductive pads on a top surface of the second top RDL 725) of the second module 704. The plurality of third vertical routing paths also includes routing paths that connect the respective third bumps of the respective third overhang portions of the plurality of third core dies to the top second RDL 725 (e.g., other conductive pads on a top surface of the second top RDL 725) of the second module 704. The lowest third core die 733a of the plurality of third core dies in the third module 706 may also be connected to the top second RDL 725 (e.g., yet other conductive pads on a top surface of the second top RDL 725) of the second module 704 through its respective plurality of third bumps, and the plurality of third vertical routing paths may also include such third vertical routing path connecting the lowest third core die 733a to the second top RDL 725.

The respective pluralities of third TSVs and the respective pluralities of third bumps of the fourth module 708 are aligned vertically forming a plurality of fourth vertical routing paths, the plurality of fourth vertical routing paths respectively connected to the top third RDL 735 (e.g., conductive pads on a top surface of the third top RDL 735) of the third module 706 through the fourth insulation layer 742. The plurality of fourth vertical routing paths also includes routing paths that connect the respective fourth bumps of the respective fourth overhang portions of the plurality of fourth core dies to the top third RDL 735 (e.g., other conductive pads on a top surface of the third top RDL 735) of the third module 706. The lowest fourth core die 743a of the plurality of fourth core dies in the fourth module 708 may also be connected to the top third RDL 735 (e.g., yet other conductive pads on a top surface of the third top RDL 735) of the third module 706 through its respective plurality of fourth bumps, and the plurality of fourth vertical routing paths may also include such fourth vertical routing path connecting the lowest fourth core die 743a to the third top RDL 735.

The top RDLs 715, 725, 735 each may include a respective routing layer with respective conductive lines for connecting the respective conductive pads on both surfaces of the top RDL connected to the respective plurality of vertical routing paths such that all core dies including the plurality of first core dies, the plurality of second core dies, the plurality of third core dies and the plurality of fourth die are all connected to the bottom RDL 711 of the first module 702 (e.g., base module) through respective pluralities of vertical routing paths and the respective routing layers of the top RDLs 715, 725, 735.

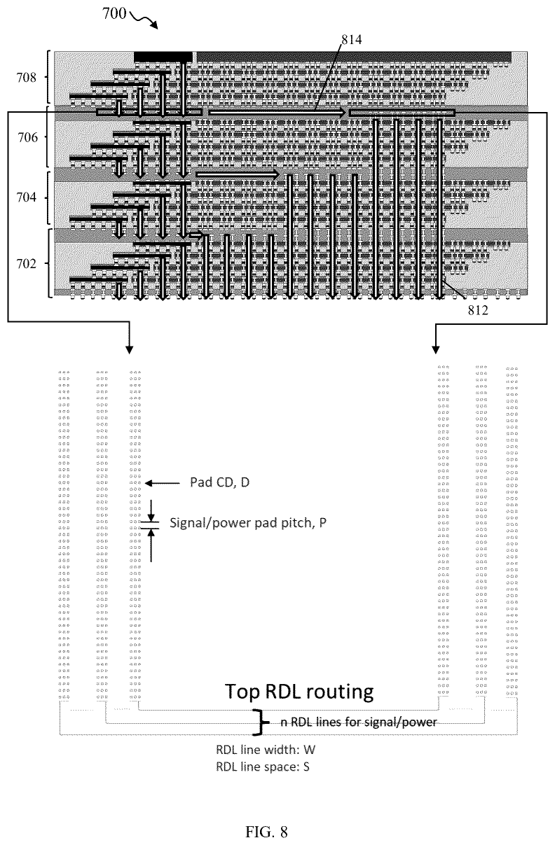

FIG. 8 shows a schematic diagram illustrating respective routing paths of the plurality of core dies in the semiconductor device 700 of FIG. 7 and a layout of the conductive pads of the top RDLs 715, 725, 735 of the semiconductor device 700 of FIG. 7. The vertical arrows (e.g., vertical arrow 812) show the respective vertical routing paths within, or across (where applicable), the modules stacked vertically in the semiconductor device 700. In this non-limiting example, as the plurality of core dies at all stacked within a (left) peripheral or edge portion of the modules and the vertical routing paths connecting the top and bottom RDLs through the plurality of TSVs of the plurality of passive dies are located at other portions of the modules, the design and pad layouts of the top RDLs 715, 725, 735 may differ such that the conductive lines of the routing layers of the top RDLs 715, 725, 735 may extend horizontally, to provide lateral connections, illustrated by horizontal arrows (e.g., horizontal arrow 814), to connect to different vertical routing paths at different portions of the modules for different modules. For example, the fourth vertical routing paths of the fourth module 708 connected to the plurality of fourth core dies are routed by the conductive lines of the routing layer of the top RDL 735 of the third module 706 to the furthest other (right) peripheral or edge portion of the modules before the respective third, second and first vertical routing paths of the third, second and first modules 706, 704, 702 route the connections to the bottom RDL 711 of the first module 702. The third vertical routing paths of the third module 706 connected to the plurality of third core dies are routed by the conductive lines of the routing layer of the second top RDL 725 to a further center portion of the modules before the respective second and first vertical routing paths of the second and first modules 704, 702 route connections to the bottom RDL 711 of the first module 702. The second vertical routing paths of the second module 704 connected to the plurality of second core dies are routed by the conductive lines of the routing layer of the top RDL 715 to the nearest center portion of the modules before the respective first vertical routing paths of the first modules 702 route connections to the bottom RDL 711 of the first module 702. This arrangement will ensure all core dies are connected to respective vertical routing paths across different modules and connected to the bottom RDL 711 of the first module 702 (e.g., base module).

Although FIG. 7 shows that the stack of dies within each module includes four dies, it is appreciated that the stack of die in each module may include any number of dies larger than two, or 1^{st} to Nth first core dies where N≥2, preferably N≤4. In one aspect, the first, second, third and fourth modules are built using an identical unit module (except top RDL 715, 725, 735). In other words, the plurality of first core dies, the plurality of first passive dies, the first insulation layer 712 and the bottom RDL may be identical to the plurality of second core dies, the plurality of second passive dies, the second insulation layer 721, and the second bottom RDL (if any) or those of the third and fourth modules 706, 708, including the lateral offsets of the plurality of dies and the layout and dimensions of the components. Alternatively, in other non-limiting aspects, the modules 702, 704, 706, 708 may not be identical, and the number of dies, the lateral offset of the dies and the layout of the components across different modules may be different. In various aspects, respective top RDL with different designs and connection pad layouts are attached on such unit modules used in different module levels to form the semiconductor device to ensure proper routing paths are formed ensuring the signal/power/data of each die of each module of a higher module level (e.g., second, third, fourth modules and beyond), can be all connected to the bottom RDL 711 of the lowest/base module 702 (e.g., base module).

In addition, the total RDL line of signal/power should be routed between pad and pad of signal/power for shortening the connections. According to various aspects described herein, the respective conductive pads (e.g., first plurality of conductive pads on the bottom surface of the top RDL 715 for connecting vertical route paths of the first module 702, and second plurality of conductive pads on the top surface of the top RDL 715 for connecting vertical routing paths of the second module 704 stacked on the first module 702) may have a predetermined size. According to the design rule shown in the following equation (1), wherein D is a diameter or size of the pad, P is the signal/power pad pitch or the space/spacing between the pads, n is the number of conductive lines (RDL lines) for signal/power, W is the width of the conductive line and S is the space/spacing between the conductive line, the respective conductive pads may have a predetermined space. The respective conductive pads may have a predetermined space/spacing from one another. The respective top conductive lines (e.g., as routing layer connecting the first plurality of conductive pads the second plurality of conductive pads) may have a predetermined space from one another. The respective top conductive lines may also have a predetermined width.

$$P - D \geq n ( S + W ) + S \qquad equation ( 1 )$$

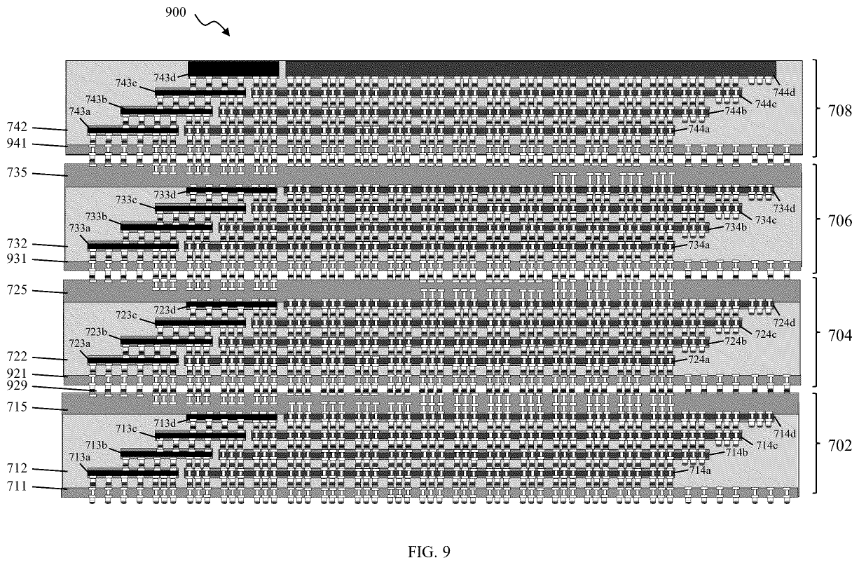

FIG. 9 shows a schematic diagram illustrating a cross-sectional view of another non-limiting semiconductor device 900 with four modules according to various aspects described herein. Such semiconductor device 900 may be fabricated through different fabrication processes. The semiconductor device 900 may include similar components with identical functions as those of the semiconductor device 800 of FIG. 8, except that there is a bottom RDL and module bumps (e.g., module bump 929) on each higher module (e.g., second, third and fourth module 704, 706, 708) that is stacked vertically on a lower module (e.g., first module 702) for connecting the higher module to the lower module. For purpose of brevity and to avoid unnecessary repetition, components that perform the same or equivalent functions across FIGS. 7 and 9 are designated using the same reference numerals. The description of components bearing the same reference numerals, as detailed in connection with FIG. 7, may be omitted or may not be repeated in detail in connection with FIG. 9. However, where applicable, additional details, specific differences, or unique aspects relevant to the particular component in FIG. 9 will be described and highlighted as follows.

The second module may further include a second bottom RDL 921 and the plurality of second core dies and the plurality of second passive dies are arranged vertically on the second bottom RDL 921. The third module may further include a third bottom RDL 931 and the plurality of third core dies and the plurality of third passive dies are arranged vertically on the third bottom RDL 931. The fourth module may further include a fourth bottom RDL 941 and the plurality of fourth core dies and the plurality of fourth passive dies are arranged vertically on the fourth bottom RDL 941. The second bottom RDL 921 may include a plurality of second module bumps protruding away from the second bottom RDL 921 which contacts with the top RDL 715 (e.g., conductive pads of the top RDL 715) and respective vertical interconnects (e.g., conductive lines and pads) respectively connecting the plurality of second module bumps to the plurality of second vertical routing paths of the second module 704 such that the plurality of second vertical routing paths are connected to the respective first vertical routing paths connected to the top RDL 715 further through the plurality of second module bumps. Similarly, the third bottom RDL 931 may include a plurality of third module bumps protruding away from the third bottom RDL 931 which contact with the second top RDL 725 (e.g., conductive pads of the second top RDL 725) and respective vertical interconnects (e.g., conductive lines and pads) respectively connecting the plurality of third module bumps to the plurality of third vertical routing paths of the third module 706 such that the plurality of third vertical routing paths are connected to the respective second vertical routing paths connected to the second top RDL 725 further through the plurality of third module bumps. The fourth bottom RDL 941 may include a plurality of fourth module bumps protruding away from the fourth bottom RDLs 941 which contact with the third top RDL 735 (e.g., conductive pads of the third top RDL 735) and respective vertical interconnects (e.g., conductive lines and pads) respectively connecting the plurality of fourth module bumps to the plurality of fourth vertical routing paths of the fourth module 708 such that the plurality of fourth vertical routing paths are connected to the respective third vertical routing paths connected to the third top RDL 735 further through the plurality of third module bumps.

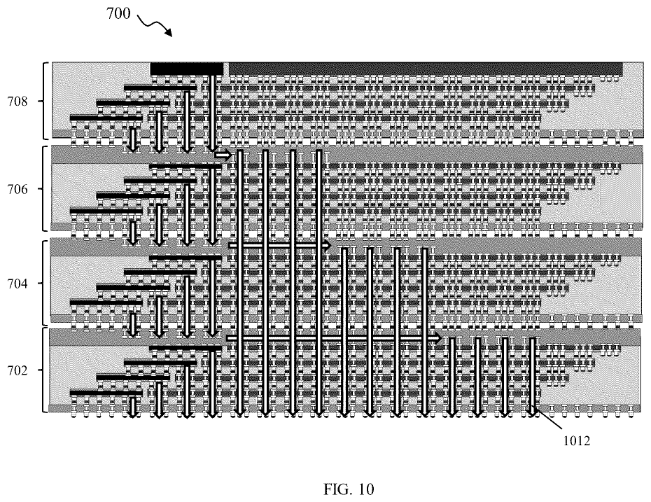

In a non-limiting example, different designs and pad layouts of the top RDLs 715, 725, 735 may be used. FIG. 10 shows a schematic diagram illustrating respective routing paths of the plurality of core dies in the semiconductor device 900 of FIG. 9 with a different layout of the conductive pads of the top RDLs 715, 725, 735 of the semiconductor device 900 of FIG. 9. The vertical arrows (e.g., vertical arrow 1012) show the respective vertical routing paths within, or across (where applicable), the modules stacked vertically in the semiconductor device 900. In this non-limiting example, The fourth vertical routing paths of the fourth module 708 connected to the plurality of fourth core dies are routed by the conductive lines of the routing layer of the top RDL 735 of the third module 706 to the nearest center portion of the modules before the respective third, second and first vertical routing paths of the third, second and first modules 706, 704, 702 route the connections to the bottom RDL 711 of the first module 702. The third vertical routing paths of the third module 706 connected to the plurality of third core dies are routed by the conductive lines of the routing layer of the second top RDL 725 to a further center portion of the modules before the respective second and first vertical routing paths of the second and first modules 704, 702 route connections to the bottom RDL 711 of the first module 702. The second vertical routing paths of the second module 704 connected to the plurality of second core dies are routed by the conductive lines of the routing layer of the top RDL 715 to a further (right) peripheral or edge portion of the modules before the respective first vertical routing paths of the first modules 702 route connections to the bottom RDL 711 of the first module 702. This arrangement will ensure all core dies are connected to respective vertical routing paths across different modules and connected to the bottom RDL 711 of the first module 702 (e.g., base module).

For purposes of avoiding clutter in the drawings, only the some of the bumps are labelled in FIGS. 7 and 9. Additionally, to avoid further clutter, each bump shown may represent a bump of a set of one or more bumps. Each die may include M interface ports (M being an integer >=1) (e.g., 1028 interface ports). For example, the first core die 713b may include M interface ports. In such case, the bumps for connecting to the first overhang portion 715b of the first core die 713b may be one bump of a set of M bumps for connecting to the M interface ports of the first core die 713b, and the other bumps of the set are not shown.

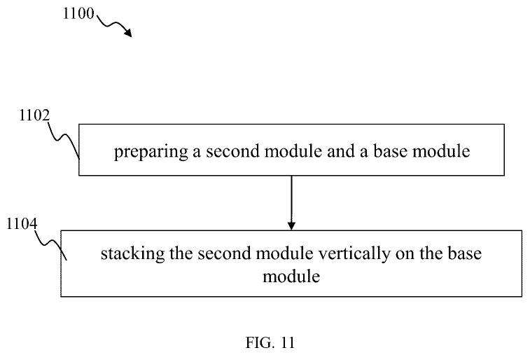

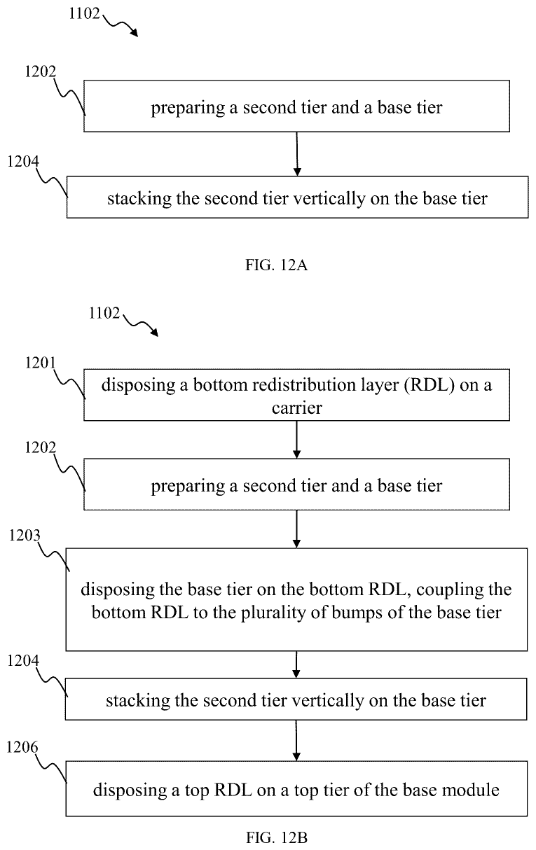

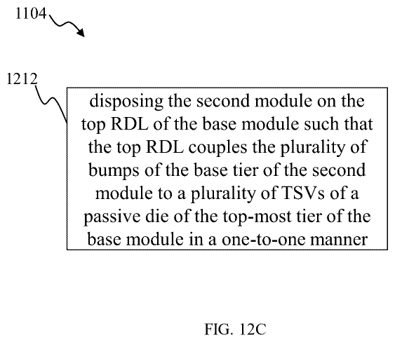

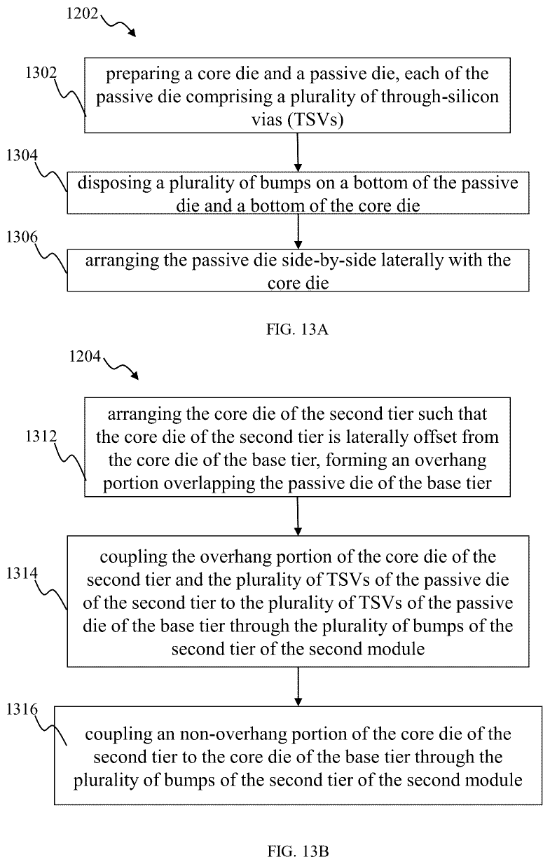

FIG. 11 shows a flow chart illustrating a method 1100 for fabricating a semiconductor device (e.g., semiconductor device 500, 550, 600, 700) according to various aspects described herein. FIGS. 12A and 12B show flow charts illustrating parts of the processes of step 1102 of the method 1100 shown in FIG. 11. FIG. 12C shows a flow chart illustrating parts of the processes of step 1104 of the method 1100 shown in FIG. 11. FIGS. 13A and 13B show flow charts illustrating parts of the processes of steps 1202 and 1204 of the method 1200 shown in FIGS. 12A and 12B.

The method 1100 may broadly include, in step 1102, preparing a second module and a base module; and in step 1104, stacking the second module vertically on the base module. The method 1100, in step 1102, for example, when preparing the second module, may include, in step 1202, preparing a second tier and a base tier, and in step 1204, stacking the second tier vertically on the base tier. The method 1100, in step 1102, for example, when preparing the base module, may include, in step 1201, disposing a bottom redistribution layer (RDL) on a carrier; in step 1202, preparing a second tier and a base tier; in step 1203, disposing the base tier on the bottom RDL, connecting the bottom RDL to the plurality of bumps of the base tier; in step 1204, stacking the second tier vertically on the base tier; and in step 1206, disposing a top RDL on a top-most tier of the base module (e.g., the second tier if the semiconductor device contains only two tiers, or a third tier if the semiconductor device contains three tiers). The method 1100, in step 1202, when preparing each of the second tier and the base tier, may include, in step 1302, preparing a core die and a passive die, each of the passive die comprising a plurality of through-silicon vias (TSVs); in step 1304, disposing a plurality of bumps on a bottom of the passive die and a bottom of the core die; and in step 1306, arranging the passive die side-by-side laterally with the core die. The method 1100, in step 1204, when stacking the second tier vertically on the base tier, may include, in step 1312, arranging the core die of the second tier such that the core die of the second tier is laterally offset from the core die of the base tier, forming an overhang portion overlapping the passive die of the base tier; in step 1314, connecting the overhang portion of the core die of the second tier and the plurality of TSVs of the passive die of the second tier to the plurality of TSVs of the passive die of the base tier through the plurality of bumps of the second tier of the second module; and in step 1316, attaching an non-overhang portion of the core die of the second tier to the core die of the base tier through the plurality of bumps of the second tier of the second module. The method 1100, in step 1104, when stacking the second module vertically on the base module, may include, in step 1212, disposing the second module on the top RDL of the base module such that the top RDL connects the plurality of bumps of the base tier of the second module to the plurality of TSVs of the passive die of the second tier of the base module in a one-to-one manner.

Stated differently, the method 1100 may broadly include preparing a first module and a second module; and arranging the first module and the second module to stack vertically on one another. method may, when preparing the first module, further include: forming a bottom RDL (e.g., bottom RDLs 511, 711) on a carrier; preparing a plurality of first core dies and a plurality of first passive dies, each of the plurality of first passive dies may include a plurality of first through-silicon vias (TSVs); arranging the plurality of first core dies and the plurality of first passive dies vertically into a plurality of first tiers on the bottom RDL; and forming a top RDL (e.g., top RDLs 515, 715). In addition, the preparing the plurality of first core dies and the plurality of first passive dies may further comprise forming a respective plurality of second bumps protruding away from the respective first core die and the respective first passive die of each first tier higher than a lowest first tier among the plurality of first tiers. Additionally, the forming the bottom RDL may further include forming a plurality of module bumps protruding away from the bottom RDL and vertical interconnects for connecting the plurality of module bumps configured to connect to another module or an external substrate or interposer through the plurality of module bumps. Additionally, after stacking the plurality of first core dies and the plurality of first passive dies, a step of forming a molding layer encapsulating the plurality of first core dies and the plurality of first passive dies and grinding the molding layer to reveal the plurality of TSVs of the plurality of first passive dies is carried out prior to forming the top RDL layer.

The method may also, when preparing the second module, further include: preparing a plurality of second core dies and a plurality of second passive dies, each of the plurality of second passive dies may include a plurality of second TSVs; and arranging the plurality of second core dies and the plurality of second passive dies vertically into a plurality of second tiers on another carrier, each of the plurality of second tiers including a second passive die of the plurality of second passive dies placed side-by-side horizontally with a second core die of the plurality of second core dies, wherein the plurality of second core dies are laterally offset from each other. In addition, the preparing the plurality of second core dies and the plurality of second passive dies may further comprise forming a respective plurality of second bumps protruding away from the respective second core die and the respective second passive die of each second tier higher than a lowest second tier among the plurality of second tiers.

As such, the first module and the second module are arranged to stack vertically on one another to align the first module and second module in a column; the plurality of first core dies and the plurality of first passive dies of the first module and the plurality of second core dies and the plurality of second passive dies of the second module are vertically aligned, so that a first core die of a lowest first tier and a second core die of a lowest second tier are vertically aligned; and each of the plurality of first through-silicon vias (TSVs) of the first module and each of the plurality of second TSVs of the second module are vertically aligned, respectively.

Additionally, each of the plurality of first core dies stacked higher than the respective first core die of the lowest first tier among the plurality of first tiers forms a respective first overhang portion overlapping the respective first passive die of a lower first tier, and each of the plurality of second core dies stacked higher than the respective second core die of the lowest second tier among the plurality of second tiers forms a respective second overhang portion overlapping the respective second passive die of a lower second tier; wherein the respective pluralities of the first TSVs, and the respective pluralities of first bumps are aligned vertically forming a plurality of first vertical routing paths, the plurality of first vertical routing paths respectively connecting the top RDL to the bottom RDL and connecting the respective first bumps of the pluralities of first bumps protruding away from the respective first overhang portions to the bottom RDL, and the respective pluralities of the second TSVs and the respective pluralities of second bumps are aligned vertically forming a plurality of second vertical routing paths, the plurality of second vertical routing paths respectively connecting the respective second bumps of the respective pluralities of second bumps protruding away from respective second overhang portions to the top RDL of the first module. In such case, the forming the top RDL may further include forming a routing layer configured to connect the plurality of second vertical routing paths to respective first vertical routing paths connected to the top RDL among the plurality of first vertical routing paths.

The forming the routing layer may further include forming a first plurality of top conductive pads respectively connected to the plurality of first vertical routing paths connecting to the top RDL and the bottom RDL, and a second plurality of top conductive pads respectively connected to the plurality of second vertical routing paths and respective conductive lines connecting the first plurality of conductive pads and the second plurality of conductive pads such that the plurality of first vertical routing paths respectively connecting the first plurality of top conductive pads of the top RDL to the first plurality of bottom conductive pads of the bottom RDL and connecting the respective first bumps of the pluralities of first bumps protruding away from the respective first overhang portions to the second plurality of bottom conductive pads of the bottom RDL, and the plurality of second vertical routing paths respectively connects respective second bumps of the respective pluralities of second bumps protruding away from the respective second overhang portions to the second plurality of top conductive pads of the top RDL of the first module, and the respective top conductive lines of the top RDL connects the plurality of second vertical routing paths to respective first vertical routing paths connected to the first plurality of top conductive pads among the plurality of first vertical routing paths.

In an aspect, a first module (e.g., base module) of a semiconductor device (e.g., semiconductor device 500, 550, 600, 700) may be separately prepared. In such case, the preparing of the first module may include forming a top RDL on a glass carrier, followed by steps to prepare the plurality of first core dies and the plurality of first passive dies, arranging the plurality of first core dies and the plurality of first passive dies vertically into a plurality of tiers on the top RDL and forming the bottom RDL. Subsequently, the glass carrier 1709 may be debonded from the top RDL to form the first module to be assembled with other modules and arranged into a semiconductor device (e.g., semiconductor device 500, 550, 600, 700).

Similarly, the second module and other modules such as the third and fourth modules (e.g., middle and top modules) of a semiconductor device (e.g., semiconductor device 500, 550, 600, 700) and the respective pluralities of second and other dies stacked within each of the second and other modules may be separately prepared in a similar manner. In such case, the separately prepared second module is assembled and arranged to stack vertically on the first module, followed by arranging and assembling other modules (if any) to further stack vertically on the second module to fabricate a semiconductor device (e.g., semiconductor device 500, 550, 600, 700). The modules may be stacked through MR or TCB bumping process so that the active dies can be stacked up to 16 dies and beyond across all stacked modules to meet high bandwidth and capacity requirements. Additionally, since the preparations of the modules are carried out separately, it is appreciated that the preparation of the first module, the second module and other modules may be carried out in any order.

In an alternative aspect, the second module (e.g., top module) is first prepared on the glass carrier and the first module (e.g., base module) is then prepared on the second module to form a base module connecting the second module. This may be referred to a sequential fanout RDP built-up module staking process. In such case, arranging the first module and the second module to stack vertically on one another includes performing the preparation of the second module first, for example, on the glass carrier, and the preparation of the first module on the second module, e.g., the second insulation layer of the second module, subsequent to the preparation of the second module. The preparing the first module may include forming a top RDL) on the second module attached to the glass carrier or attached to another carrier (e.g., a third module), followed by steps to prepare the plurality of first core dies and the plurality of first passive dies, arranging the plurality of first core dies and the plurality of first passive dies vertically into a plurality of tiers on the top RDL and forming the bottom RDL. Subsequently, after the preparation of the first module on the second module 1700, the glass carrier 1709 may be debonded from the top module (e.g., the second module) to form a semiconductor device (e.g., semiconductor device 500, 550, 600, 700).

According to various aspects described herein, the process of forming an RDL layer (e.g., top RDL and bottom RDL) may begin with the application of polyimide coating, providing insulation and protection. Photolithography may then define intricate patterns on the polyimide layer using light-sensitive photoresist materials. After curing to stabilize the polyimide, titanium (Ti) (e.g. 1000 angstroms) and copper (Cu) (e.g. 3000 angstroms) may be sequentially deposited using PVD, forming adhesion layers and conductive traces, respectively. Additional photolithography steps may refine these layers, followed by electroplating to build up copper thickness and photoresist stripping to reveal the patterned traces. Etching of the seed layer may ensure precise alignment and connectivity for subsequent layers. This process may be repeated for each RDL. The RDL forming process may further include a process of fabricating conductive pads which begin with applying a polyimide coating onto the substrate, providing electrical insulation and physical protection. Photolithography may follow, where patterns are defined on the polyimide layer using light-sensitive photoresist materials, for guiding subsequent metallization steps. The polyimide may be then cured to stabilize its structure and optimize its properties for semiconductor applications. Next, titanium (Ti) and copper (Cu) may be sequentially deposited using PVD, with titanium serving as an adhesion layer and copper forming the conductive traces for interconnections. Additional photolithography steps may refine the copper layer, defining intricate circuit patterns. Electroplating may be employed to increase the thickness of the copper traces, ensuring they can efficiently conduct electrical currents. Subsequently, the photoresist layer may be stripped away, leaving behind the desired patterned copper traces. Etching of the seed layer may complete the process, ensuring precise alignment and connectivity for subsequent layers or components.

Arranging or stacking a core die and a passive die on an RDL layer may include Pick-N-Press process and reflow soldering process. The Pick-N-Press process may involve automated machinery that picks up the dies from supply sources and accurately positions them onto designated spots on the RDL. In the context of various aspects, the Pick-N-Press process may include placing the core die and the corresponding passive die side-by-side in a respective tier. The reflow soldering process may create electrical connections between the dies and the RDL. It may begin with applying solder paste, a mixture of solder alloy and flux, onto the conductive pads of the RDL. The assembled board may then pass through a reflow oven where it undergoes controlled heating stages. The solder paste may melt, flow, and solidify to securely bond the dies to the RDL, forming robust solder joints.

The bump formation process may involve several steps: starting with PVD of Titanium (Ti) at 1,000 angstroms and PVD of Copper (Cu) at 3,000 angstroms to create a seed layer; followed by photolithography to define the bump locations; electroplating to build up the metal (e.g. Cu); stripping the photoresist; etching away the unnecessary seed layer; reflowing to form bumps; and descumming to clean the surface.

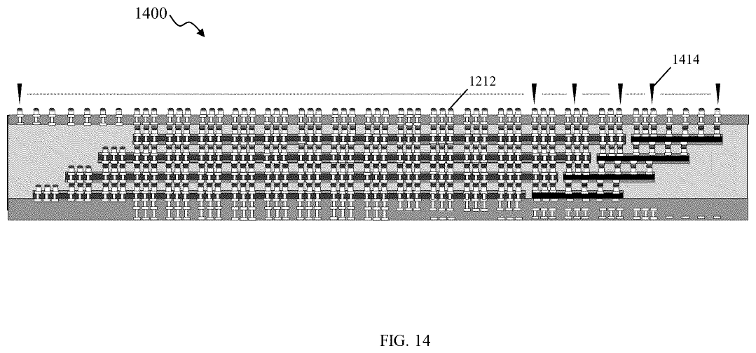

In a non-limiting aspect, a Known Good Unit Module (KGM) testing step may be carried out during the fabrication process after a module is prepared and before the module is assembled to form a semiconductor device. FIG. 14 shows a cross-sectional view of a module 1400 (e.g., base, middle, top modules) when a KGM step is carried out after the preparation of the module 1400. The module 1400 may be fabricated according to the method 1100 and include an RDL, an insulation layer on the bottom RDL, a plurality of core dies and a plurality of passive dies arranged vertically into a plurality of tiers within the first insulation layer on the bottom RDL, and a top RDL. Each of the plurality of passive dies includes a plurality of TSVs. Each tier, more particularly, the respective core die and the respective passive die of each tier, further includes a respective plurality of first bumps protruding away from the each first tier, and the plurality of first tiers are stacked vertically on each other through such respective pluralities of first bumps. The bottom RDL may further include a plurality of module bumps (e.g., module bump 1412) protruding away from the bottom RDL and vertical interconnects for connecting a plurality of vertical routing paths and the plurality of first core dies of the module to another module or an external substrate or interposer. Subsequent to preparing the module, the method 1100 may further include performing a test (e.g., KGM test) using test probes (e.g., test probe 1414) to measure respective electrical properties of the module, for example, to identify any defective die and connection. The minimum size of the pitch is equal to or larger than 50 μm and the testing pad is equal to or larger than 20 μm. Any probe mark can be removed by 2^{nd} reflow.

The following paragraphs describe an improved core die (e.g., memory chip, logic die) with mix bump designs for building high bandwidth memory stacks in accordance with the second and third aspects described herein.

According to the various aspect, to address the coplanarity issue of a module having multiple tiers of core dies and passive dies stacked vertically on one another, a mixed bump designs may be implemented, that is the stack of core dies have two types of bump: (1) bumps protruding from a core die of a higher tier (e.g., a second tier, a third tier) connecting another core die of a lower tier (e.g., base tier in case of second tier, second tier in case of third tier) having bigger diameter and/or higher solder volume providing mechanical connection between the core dies; and (2) bumps connecting a core die (e.g. an overhang portion of the core die) and the passive die (e.g., TSV die) have smaller diameter and/or solder volume providing the electrical connections. In particular, the semiconductor device may include bottom redistribution layer (RDL); a first passive die arranged side-by-side laterally with a first core die in a base tier on the base RDL; and a second passive die arranged side-by-side laterally with a second core die in a second tier stacked vertically on the base tier, wherein the second core die is laterally offset from the first core die, forming an overhang portion overlapping the first passive die; wherein each of the first and second passive dies comprises a plurality of through-silicon vias (TSVs); and wherein the second tier comprises a plurality of bumps disposed on a bottom of the second passive die and a bottom of the second core die, the plurality of bumps of the second tier comprises a first type of bump configured to connect the overhang portion of the second core die and the plurality of TSVs of the second passive die to the plurality of TSVs of the first passive die, and a second type of bump configured to attach a non-overhang portion of the second core die (e.g., a portion of the second core die other than the overhang portion) to the first core die. The first type of bump has bigger bumps with more solder volumes, for example a larger diameter, a greater protrusion height and/or a wider pitch than that of the second type of bump. Advantageously, the bigger bumps with more solder volume connecting two core dies stacked vertically on one another can help to modulate the chip gaps and compensate the core die and TSVs die stack height variations in the multiple tiers structure. Various aspects below illustrate such mixed bump design with two types of bump in a stack of memory dies or chips of a memory unit or module. It is appreciated that such mixed bump design is also applicable to stack of other core dies such as logic dies of a logic chip unit or other semiconductor devices.

Additionally, the semiconductor device may include more than two tiers stacked vertically on one another (e.g., a third tier stacked vertically on the second tier). In such case, the semiconductor device includes a third passive die arranged side-by-side laterally with a third core die in a third tier stacked vertically on the second tier, wherein the third core die is laterally offset from the second core die, forming an overhang portion overlapping the second passive die of the second tier. The third tier includes a plurality of bumps disposed on a bottom of the third passive die and a bottom of the third core die of the third tier, the plurality of bumps of the third tier comprises the first type of bump configured to connect to the overhang portion of the third core die and the plurality of TSVs of the third passive die to the plurality of TSVs of the second passive die, and the second type of bump configured to attach a non-overhang portion of the third core die to the second core die. The first type of bump has bigger bumps with more solder volumes, for example a larger diameter, a greater protrusion height and/or a wider pitch than that of the second type of bump.

FIG. 15A shows a schematic diagram illustrating a non-limiting core die 1500 (e.g., memory chip) having a first mixed bump design according to various aspects described herein. The core die 1500 has a plurality of bumps protruding away from a bottom surface. Each bump has a pillar (e.g., pillar 1502a, 1504a) protruding away from the core die 1500 and a solder tip (e.g., solder tip 1502b, 1504b) protruding away from the pillar. The plurality of bumps may include two types of bumps, a first type of bump (e.g., bump 1502) at one portion 1501 of the core die 1500 has a smaller/narrower pitch, smaller bump (e.g., smaller in size, protrusion height and/or diameter) and/or a lower solder volume, while a second type of bump (e.g., bump 1504) at another portion 1503 of the core die 1500 have a bigger/wider pitch (i.e., bump-to-bump spacing) and/or a bigger bump (e.g., greater in size, protrusion height and/or diameter) and a higher solder volume. According to the first mixed bump design, both the first type of bump and the second type of bump are Cu/Solder bumps. That is, the pillars of both first type of bump and second type of bump protruding away from the dies are Cu pillars and the tips of both first type of bump and second type of bump extending away from the Cu pillar are solder tips.

FIG. 15B shows a schematic diagram illustrating a cross-sectional view of a non-limiting module 1510 with the first mixed bump design according to the various aspects described herein. The module 1510 may have a plurality of core dies (e.g., core dies 1513-1, 1513-2, 1513-3 . . . 1513-N) and a plurality of passive dies (e.g., passive dies 1514-1, 1514-2, 1514-3 . . . 1514-N) arranged vertically into a plurality of tiers on a bottom RDL 1511. Each of the plurality of tiers includes a respective passive die of the plurality of passive dies 1514 placed side-by-side horizontally with a respective core die of the plurality of core dies 1513 (e.g., a passive die 1514-1 with a core die 1513). The plurality of core dies are laterally offset from each other, each of the plurality of core dies stacked higher than the respective core die of a lowest tier among the plurality of tiers forms a respective overhang portion (e.g., overhang portion 1515 of core die 1513-3) overlapping the respective passive die of a lower tier (e.g., passive die 1514-1). Each of the plurality of passive dies may include a plurality of TSVs (e.g., TSV 1516).

The module 1510 may further include a respective plurality of bumps (e.g., bumps 1518, 1517) protruding away from the respective core die (e.g., core dies 1513-2, 1513-3, 1513-N) and the respective passive die (e.g., passive dies 1514-2, 1514-3, 1514-N) of each tier stacked higher than the lowest tier with the core die 1513-1 and the passive die 1514-1 attached to the bottom RDL 1511. The plurality of tiers is stacked vertically on one another through the respective pluralities of bumps. The respective pluralities of the TSVs are vertically aligned. For example, the respective pluralities of the TSVs and the respective pluralities of bumps of the plurality of tiers may be aligned vertically forming a plurality of vertical routing paths, the plurality of vertical routing paths respectively connecting the respective bumps of the respective pluralities of bumps protruding away from the respective overhang portions (e.g., overhang portion 1515) to the bottom RDL.

The respective plurality of bumps of a tier may include two different types of bumps: a first type of bump (e.g., bump 1517) protruding away from the respective passive die (e.g., passive die 1514-3) and the respective overhang portion (e.g., overhang portion 1515) of the respective core die (e.g., core die 1513-3) of such tier configured to connect to the TSVs of the respective passive die (e.g., passive die 1514-2) of a lower tier and a second type of bump (e.g., bump 1508) protruding away from the remaining portion (e.g., remaining portion 1519 of core die 1513-3) configured to connect to the respective core die (e.g., core die 1513-2) of the lower tier.

In this non-limiting example, the first type of bump (e.g., bump 1517) protruding away from the respective passive die (e.g., passive die 1514-3) and the respective overhang portion (e.g., overhang portion 1515) have smaller/narrower pitch, a smaller bump (e.g., smaller in size, height and/or diameter) and/or a lower solder volume while the second type of bump (e.g., bump 1518) at other portion (e.g., portion 1519) of the core die have a bigger/wider pitch, a bigger bump (e.g., greater in size, height and/or diameter) and/or a higher solder volume. According to the first mixed bump design, both the first type of bump and the second type of bump are Cu/Solder bumps. That is, the pillars of both first type of bump and second type of bump protruding away from the dies are Cu pillars and the tips of both first type of bump and second type of bump extending away from the Cu pillar are solder tips.

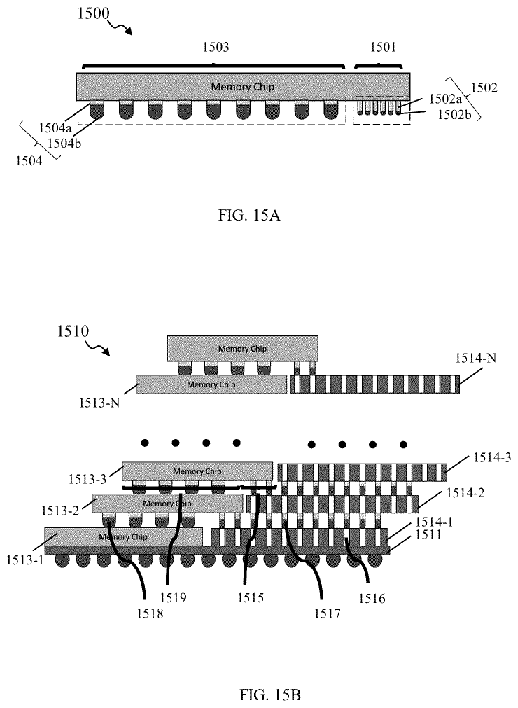

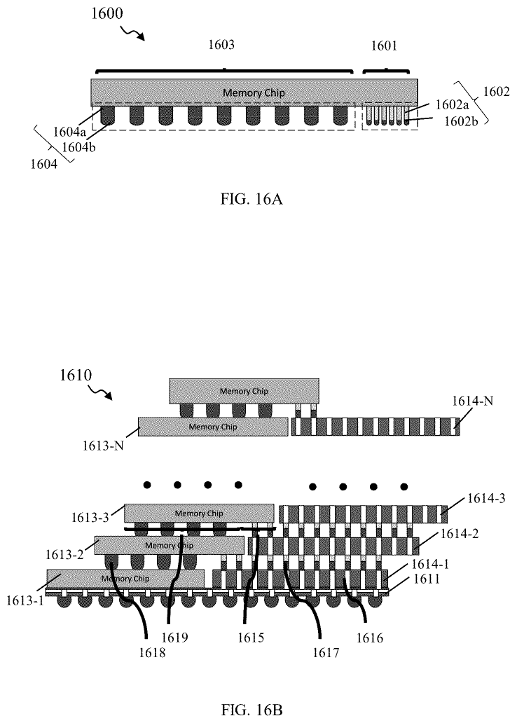

FIG. 16A shows a schematic diagram illustrating a non-limiting core die 1600 (e.g., memory chip) having a second mixed bump design according to various aspects described herein. The core die 1600 has a plurality of bumps protruding away from a bottom surface. Each bump has a pillar (e.g., pillar 1602a, 1604a) protruding away from the core die 1600 and a solder tip (e.g., solder tip 1602b, 1604b) protruding away from the pillar. The plurality of bumps may include two types of bumps, a first type of bump (e.g., bump 1602) at one portion 1601 of the core die 1600 has a smaller/narrower pitch, smaller bump (e.g., smaller in size, height and/or diameter) and a lower solder volume, while a second type of bump (e.g., bump 1604) at another portion 1603 of the core die 1600 have a bigger/wider pitch (i.e., bump-to-bump spacing), a bigger bump (e.g., greater in size, height and/or diameter) and a higher solder volume. According to the second mixed bump design, the first type of bump are pure solder bumps, that is, both the pillars and tips of the first type of bump are made of a same solder material, whereas the second type of bump are Cu/Solder bumps, that is, the pillars of the second type of bump protruding away from the dies are Cu pillars and the tips of the second type of bump extending away from the Cu pillar are solder tips.

FIG. 16B shows a schematic diagram illustrating a cross-sectional view of a non-limiting module 1610 with the second mixed bump design according to the various aspects described herein. The module 1610 has a plurality of core dies (e.g., core dies 1613-1, 1613-2, 1613-3 . . . 1613-N) and a plurality of passive dies (e.g., passive dies 1614-1, 1614-2, 1614-3 . . . 1614-N) arranged vertically into a plurality of tiers on a bottom RDL 1611. Each of the plurality of tiers including a respective passive die of the plurality of passive dies 1614 placed side-by-side horizontally with a respective core die of the plurality of core dies 1613 (e.g., a passive die 1614-1 with a core die 1613). The plurality of core dies are laterally offset from each other, each of the plurality of core dies stacked higher than the core die of a lowest tier among the plurality of tiers forms a respective overhang portion (e.g., overhang portion 1615 of core die 1613-3) overlapping the respective passive die of a lower tier (e.g., passive die 1614-1). Each of the plurality of passive dies may include a plurality of TSVs (e.g., TSV 1616).

The module 1610 may further include a respective plurality of bumps (e.g., bumps 1618, 1617) protruding away from the respective core die (e.g., core dies 1613-2, 1613-3, 1613-N) and the respective passive die (e.g., passive dies 1614-2, 1614-3, 1614-N) of each tier stacked higher than the lowest tier with the core die 1613-1 and the passive die 1614-1 attached to the bottom RDL 1611. The plurality of tiers are stacked vertically on one another through the respective pluralities of bumps. The respective pluralities of TSVs may be vertically aligned. For example, the respective pluralities of the TSVs and the respective pluralities of bumps of the plurality of tiers may be aligned vertically forming a plurality of vertical routing paths, the plurality of vertical routing paths respectively connecting the respective bumps of the respective pluralities of bumps protruding away from the respective overhang portions (e.g., overhang portion 1615) to the bottom RDL.

The respective plurality of bumps of a tier may include two different types of bumps: a first type of bump (e.g., bump 1617) protruding away from the respective passive die (e.g., passive die 1614-3) and the respective overhang portion (e.g., overhang portion 1615) of the respective core die (e.g., core die 1613-3) of such tier configured to connect to the TSVs of the respective passive die (e.g., passive die 1614-2) of a lower tier and a second type of bump (e.g., bump 1608) protruding away from the remaining portion (e.g., remaining portion 1619 of core die 1603-3) configured to connect to the respective core die (e.g., core die 1613-2) of the lower tier.

In this non-limiting example, the first type of bump (e.g., bump 1617) protruding away from the respective passive die (e.g., passive die 1614-3) and the respective overhang portion (e.g., overhang portion 1615) have smaller/narrower pitch, a smaller bump (e.g., smaller in size, height and/or diameter) and/or a lower solder volume while the second type of bump (e.g., bump 1618) at other portion (e.g., remaining portion 1619) of the core die have a bigger/wider pitch, a bigger bump (e.g., greater in size, height and/or diameter) and/or a higher solder volume. According to the first mixed bump design, both the first type of bump and the second type of bump are Cu/Solder bumps. That is, the pillars of both first type of bump and second type of bump protruding away from the dies are Cu pillars and the tips of both first type of bump and second type of bump extending away from the Cu pillar are solder tips.

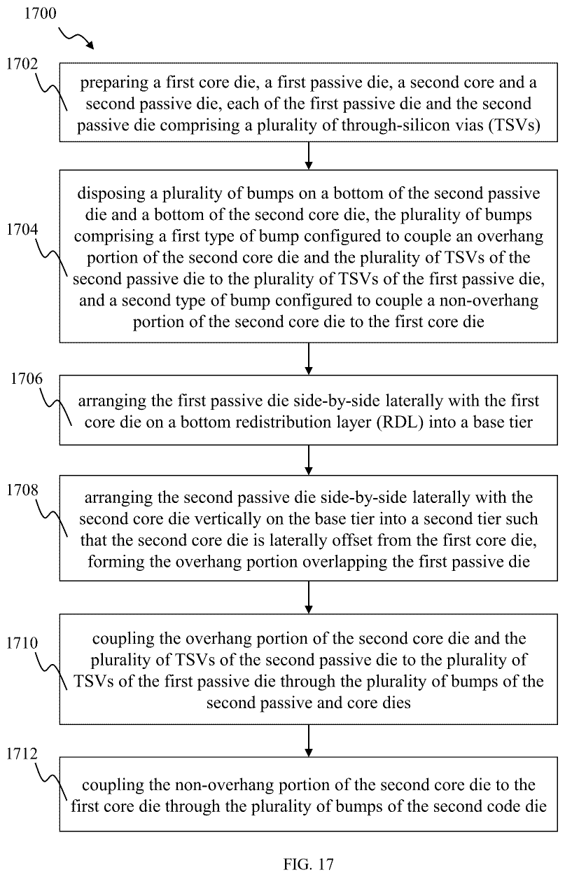

FIG. 17 shows a flow chart illustrating a method 1700 for fabricating a semiconductor device (e.g., semiconductor device 1600, 1610) according to various aspects described herein. The method 1700 may broadly include preparing a plurality of core dies (e.g., first core die, second core die) and a plurality of passive dies (e.g., first passive die, second passive die), each of the plurality of passive dies may include a plurality of through-silicon vias (TSVs); and arranging the plurality of core dies and the plurality of passive dies vertically into a plurality of tiers (e.g., base tier, second tier) on a bottom RDL, each of the plurality of tiers including a respective passive die of the plurality of passive dies placed side-by-side horizontally with a respective core die of the plurality of core dies, wherein the plurality of core dies are laterally offset from each other and the respective pluralities of TSVs of the plurality of passive dies are vertically aligned. According to various aspects described herein, the preparing the plurality of core dies and the plurality of passive dies further comprises forming a respective plurality of bumps protruding away from the respective core die and the respective passive die of each tier higher than a lowest tier among the plurality of tiers, the respective plurality of bumps comprising a first type of bump for connecting to the respective plurality of TSVs of the respective passive die of a lower tier and a second type of bump protruding for attaching to the respective core die of the lower tier. In particular, the method 1700 may include, in step 1702, preparing a first core die, a first passive die, a second core and a second passive die, each of the first passive die and the second passive die including a plurality of TSVs; in step 1704, disposing a plurality of bumps on a bottom of the second passive die and a bottom of the second core die, the plurality of bumps including a first type of bump configured to connect an overhang portion of the second core die and the plurality of TSVs of the second passive die to the plurality of TSVs of the first passive die, and a second type of bump configured to attach a non-overhang portion of the second core die to the first core die; in step 1706, arranging the first passive die side-by-side laterally with the first core die on a bottom redistribution layer (RDL) in a base tier; in step 1708, arranging the second passive die side-by-side laterally with the second core die vertically on the base tier in a second tier such that the second core die is laterally offset from the first core die, forming the overhang portion overlapping the first passive die; in step 1710, connecting the plurality of TSVs of the passive die and the overhang portion of the core die of the second tier (i.e., the first type of bump) to the plurality of TSVs of the passive die of the base tier through the plurality of bumps of the second tier; and in step 1712, attaching the non-overhang portion of the second core die (i.e., the second type of bump) to the first core die through the plurality of bumps of the second tier. The plurality of bumps of the second tier of the first type disposed under the TSVs of the passive die of the second tier and under the overhang portion of the core die of the second tier. The plurality of bumps of the second tier of the second type disposed under the non-overhang portion of the core die of the second tier.

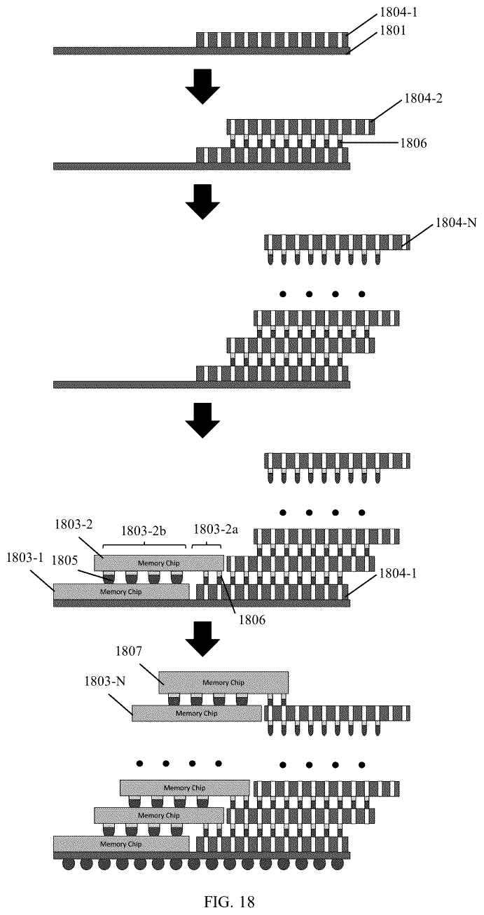

FIG. 18 shows a schematic diagram illustrating a method for fabricating a semiconductor device (e.g., semiconductor device 1510, 1610) according to various aspects described herein. The method may start by forming a passive die 1804-1 on a bottom RDL 1801, and arranging another passive die 1804-2 vertically on the passive die 1804-1 with a first type of bump 1806, the passive die 1804-2 laterally offset from the passive die 1804-1. The process of stacking the passive die may be repeated until the final passive die 1804-N is stacked forming N tiers of passive dies. Each of the passive dies 1804-1, 1804-2, 1804-N include a plurality of TSVs. The method may further include forming a core die 1803-1 on the bottom RDL 1801. The core die 1803-1 is placed side-by-side horizontally with the passive die 1804-1. The method may further include arranging another core die 1803-2 to stack vertically on the core die 1803-1 and side-by-side horizontally with the passive die 1804-2. The core die 1803-2 is laterally offset from the core die 1803-1 forming an overhang portion 1803-2a overlapping the passive die 1804-1 of a lower tier. The core die 1803-2 has a first type of bump 1806 protruding away from the overhang portion 1803-2a and connected to the passive die 1804-1, has a second type of bump 1805 protruding away from other portions 1803-2b of the core die 1803-2 and connected to the core die 1803-1 of the lower tier. The process of stacking the core die may be repeated until the final core die 1803-N is stacked forming N tiers of core dies, and the method may further include stacking a controller die or another core die (e.g., memory die) 1807 on the final core die 1803-N. The respective pluralities of the TSVs and the respective pluralities of bumps of the semiconductor device are aligned vertically forming a plurality of vertical routing paths, the plurality of vertical routing paths respectively connecting the respective bumps of the respective pluralities of bumps protruding away from the respective overhang portions to the bottom RDL (e.g., conductive pads and bumps of the bottom RDL).

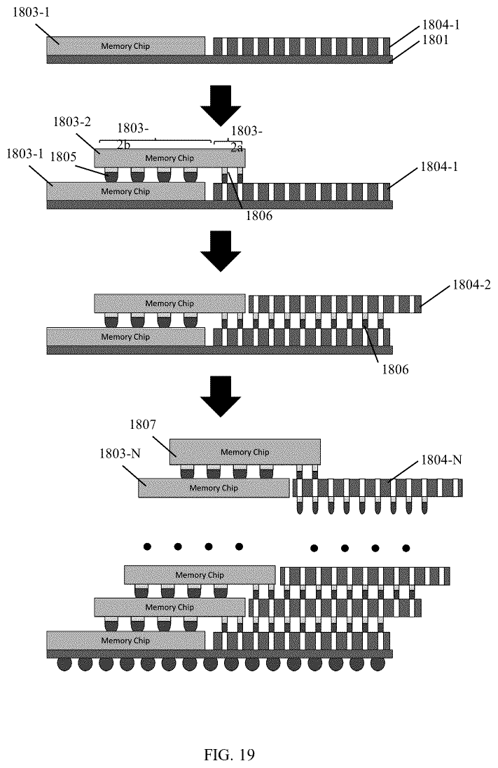

FIG. 19 shows a schematic diagram illustrating another method for fabricating a semiconductor device (e.g., semiconductor device 1510, 1610) according to various aspects described herein. The method may start by forming a core die 1803-1 and a passive die 1804-1 on a bottom RDL 1801. The core die 1803-1 is placed side-by-side horizontally with the passive die 1804-1. The method may include arranging another core die 1803-2 to stack vertically on the core die 1803-1. The core die 1803-2 is laterally offset from the core die 1803-1 forming an overhang portion 1803-2a overlapping the passive die 1804-1 of a lower tier. The core die 1803-2 has a first type of bump 1806 protruding away from the overhang portion 1803-2a and connected to the passive die 1804-1, has a second type of bump 1805 protruding away from other portions 1803-2b of the core die 1803-2 and connected to the core die 1803-1 of the lower tier. The method may further include arranging another passive die 1804-2 vertically on the passive die 1804-1 with a first type of bump 1806, the passive die 1804-2 laterally offset from the passive die 1804-1. The process of stacking the core die and the passive die may be repeated until the final core die 1803-N and the final passive die 1804-N are stacked forming N tiers of core dies and passive dies. Each of the passive dies 1804-1, 1804-2, 1804-N include a plurality of TSVs. The method may further include stacking a controller die or another core die (e.g., memory die) 1807 on the final core die 1803-N. The respective pluralities of the TSVs and the respective pluralities of bumps of the semiconductor device are aligned vertically forming a plurality of vertical routing paths, the plurality of vertical routing paths respectively connecting the respective bumps of the respective pluralities of bumps protruding away from the respective overhang portions to the bottom RDL (e.g., conductive pads and bumps of the bottom RDL).

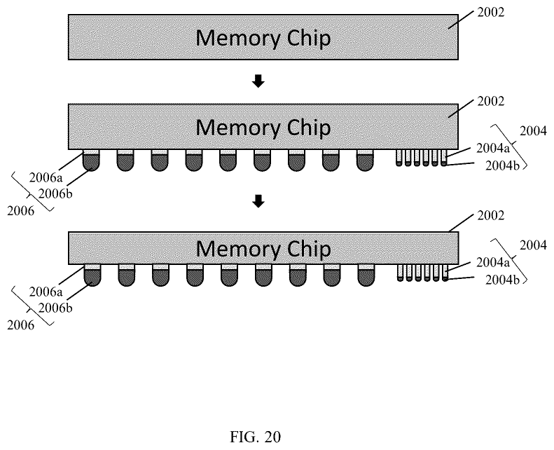

FIG. 20 shows a schematic diagram illustrating a method for fabricating a core die 2002 with a first mixed bump design according to various aspects described herein. The method may start by forming both types of bumps 2004, 2006, which both are Cu/solder bumps, protruding away from a bottom surface at different portions of the core die 2002. In other words, according to the first mixed bump design, both types of bumps 2004, 2006 are Cu pillars 2004a, 2006a protruding away from the bottom surface at the different portions of the core die 2002 and solder bumps 2004b, 2006b protruding away from the respective Cu pillars using plating process. The first type of bump 2004 has a smaller/narrower pitch, a smaller bump (e.g., smaller in size, height and/or diameter) and/or a lower solder volume while the second type of bump for connecting to and aligning with TSVs of a passive die and providing electrical connections, while the second type of bump 2006 has a bigger/wider pitch, a bigger bump (e.g., greater in size, height and/or diameter) and/or a higher solder volume for providing mechanical connection with another core die stacked underneath the core die 2002. The method may further include thinning the core die 2002 from the top surface to achieve the right thickness.

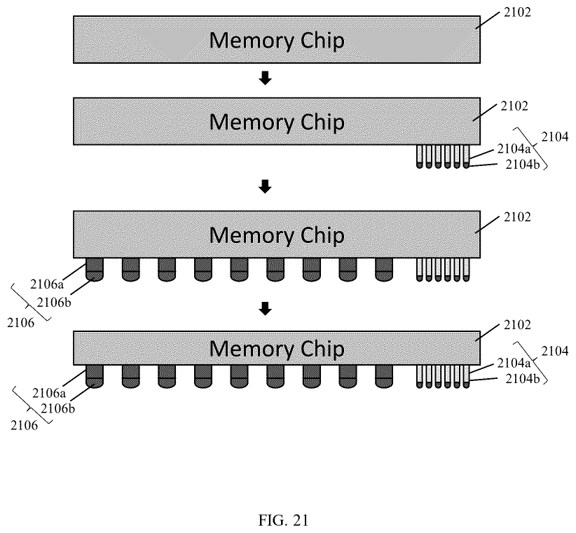

FIG. 21 shows a schematic diagram illustrating a method for fabricating a core die 2102 with a second mixed bump design according to various aspects described herein. The method may start by forming a first type of bump 2104, which is a Cu/solder bump (Cu pillar+solder bump), protruding away from a bottom surface at one (right) portion of the core die 2102 using a plating process. The method may then include forming a second type of bump 2106 which is a pure solder bump, protruding away from the bottom surface of another (left) portion of the core die 2102 using a solder paste printing process. In other words, according to the second mixed bump design, the first type of bump 2104 has Cu pillars 2104a protruding away from the bottom surface at the one (right) portion of the core die 2102 and solder bumps 2104b protruding away from the respective Cu pillars using plating process, whereas the second type of bump 2106 has both the pillar 2106a and bump 2106b made of a same solder material. The first type of bump 2104 has a smaller/narrower pitch, a smaller bump (e.g., smaller in size, height and/or diameter) and/or a lower solder volume for connecting to and aligning with TSVs of a passive die and providing electrical connections, while the second type of bump 2106 has a bigger/wider pitch, a bigger bump (e.g., greater in size, height and/or diameter) and/or a higher solder volume for providing mechanical connections with another core die stacked underneath the core die 2102. The method may further include thinning the core die 2102 from the top surface to achieve the right thickness.

Although FIGS. 15A to 21 and their accompanying descriptions above mainly describe an improved core die (e.g., memory chip, logic die) with mixed bump designs for building a single module having multiple tiers of core die, it is appreciated that the improved core die with mixed bump designs can also be applied for building a semiconductor device (e.g., semiconductor device 500, 550, 600, 700) with multiple stacked modules. In particular, in semiconductor device 500, 550, 600, 700, where each tier of the plurality of tiers of each module may include a respective plurality of bumps protruding away from the respective core die and the respective passive die, and the plurality of tiers are stacked vertically on each other through such respective pluralities of bumps. The plurality of bumps of the respective core die and the respective passive die of each tier higher than the lowest tier among the plurality of tiers of each module may include two different types of bumps. The first type of bump protrudes from the respective overhang portion of the respective core die and the respective passive die of the each tier for connecting to and aligning with TSVs of the respective passive die of a lower tier in each module for providing electrical connections, and the second type of bump protrudes from the remaining portion of the respective core die of the each tier for providing mechanical connections with the respective core die of a lower tier stacked underneath the core die. The first type of bump may have a smaller/narrower pitch, a smaller bump (e.g., smaller in size, height and/or diameter) and/or a lower solder volume, while the second type of bump 2106 may have a bigger/wider pitch, a bigger bump (e.g., greater in size, height and/or diameter) and/or a higher solder volume. Similarly, either the first mixed bump design (i.e., Cu/Solder bumps for both types of bumps) or the second mixed bump design (pure solder bumps for core-die-to-core-die connections and Cu/Solder bumps for core-die-to-passive-die connection) may be applied.

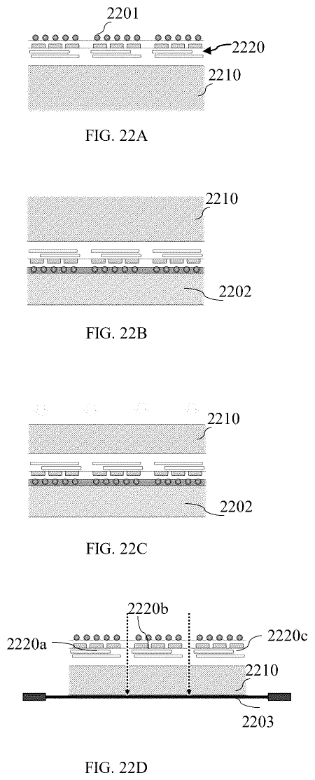

FIGS. 22A to 22D show schematic diagrams for a method of fabricating a plurality of core dies according to various aspects described herein.

FIG. 22A shows μ-bump formation process. The μ-bump formation process may include the creation of tiny solder bumps 2201, for connecting dies 2220a, 2220b, 2220c (e.g. core dies, controller die or base die) fabricated on a wafer 2210 (e.g. a DRAM wafer). The μ-bump formation process may involve several steps: starting with Physical Vapor Deposition (PVD) of Titanium (Ti) at 1,000 angstroms and PVD of Copper (Cu) at 3,000 angstroms to create a seed layer; followed by photolithography to define the bump locations; electroplating to build up the metal (e.g. Cu); stripping the photoresist; etching away the unnecessary seed layer; reflowing to form the bumps 2201; and descumming to clean the surface.

FIG. 22B shows carrier bond process. The carrier bond process may provide temporary support for wafers during various fabrication processes such as thinning, etching, and deposition. The carrier bond process may involve attaching the wafer 2210 to a carrier 2202, typically made of materials like glass or silicon, using a temporary adhesive such as thermal release tape or UV-curable adhesive. The carrier bond process may ensure mechanical stability and precise alignment, preventing damage to the thin, fragile wafers. The carrier bond process may include edge trimming to remove excess material from the edges of the wafer 2210 using mechanical or chemical methods, spin-coating that applies a uniform thin film of photoresist or other materials onto the wafer surface, and tungsten carbide (W2C) bonding process that involves depositing a thin layer of tungsten carbide onto the wafer or die surfaces and then applying pressure and heat to form a strong bond.

FIG. 22C shows backside grinding process. The backside grinding process may include two steps: background taping and backside grinding. The background taping may be the process of applying a protective adhesive tape to the front side of the wafer 2210, ensuring the delicate circuitry is shielded from mechanical stress and contamination during grinding. Following this, backside grinding may thin the wafer 2210 from the backside to the desired thickness through coarse and fine grinding stages. Coarse grinding may rapidly reduce the wafer's thickness using a diamond wheel, while fine grinding may achieve the precise final thickness and a smooth surface.

FIG. 22D shows de-bonding and die saw process. The de-bonding and die saw process may involve several steps to transform the fabricated dies 2220a, 2220b, 2220c (collectively 2220) into functional electronic components ready for integration into devices. Initially, the fabricated dies 2220 may undergo de-bonding to separate them from the carrier 2202. These individual dies 2220a, 2220b, 2220c may be then carefully mounted onto frames 2203 to provide structural support. Subsequent steps may include cleaning off residual adhesives to ensure pristine surfaces for further processing. Non-conductive film (NCF) lamination may follow, where layers are bonded using specialized techniques like laser grooving and vias (LGV) to facilitate electrical connections and mechanical support. Finally, die sawing may precisely cut the assembled components into individual dies 2220a, 2220b, 2220c, ensuring each is ready for packaging and integration into electronic products.

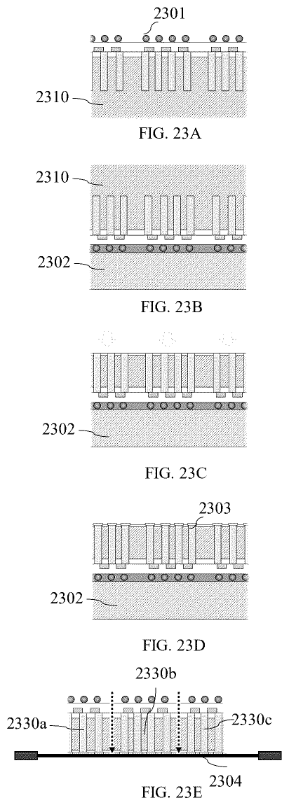

FIGS. 23A to 23E show schematic diagrams for a method of fabricating a plurality of passive dies, each of which has a plurality of through-silicon vias according to various aspects described herein.

FIG. 23A shows μ-bump formation process. The μ-bump formation process may include the creation of tiny solder bumps 2301 for connecting dies 2320a, 2320b, 2320c (e.g. passive dies) fabricated on a wafer 2310. The μ-bump formation process may involve several steps: starting with Physical Vapor Deposition (PVD) of Titanium (Ti) at 1,000 angstroms and PVD of Copper (Cu) at 3,000 angstroms to create a seed layer; followed by photolithography to define the bump locations; electroplating to build up the metal (e.g. Cu); stripping the photoresist; etching away the unnecessary seed layer; reflowing to form the bumps 2301; and descumming to clean the surface.

FIG. 23B shows carrier bond process. The carrier bond process may provide temporary support for wafers during various fabrication processes such as thinning, etching, and deposition. The carrier bond process may involve attaching the wafer 2310 to a carrier 2302, typically made of materials like glass or silicon, using a temporary adhesive such as thermal release tape or UV-curable adhesive. The carrier bond process may ensure mechanical stability and precise alignment, preventing damage to the thin, fragile wafers. The carrier bond process may include edge trimming to remove excess material from the edges of the wafer 2310 using mechanical or chemical methods, spin-coating that applies a uniform thin film of photoresist or other materials onto the wafer surface, and tungsten carbide (W2C) bonding process that involves depositing a thin layer of tungsten carbide onto the wafer or die surfaces and then applying pressure and heat to form a strong bond.

FIG. 23C shows backside grinding and isolation process. The backside grinding may include two steps: background taping and backside grinding. The background taping may be the process of applying a protective adhesive tape to the front side of the wafer 2310, ensuring the delicate circuitry is shielded from mechanical stress and contamination during grinding. Following this, backside grinding may thin the wafer 2310 from the backside to the desired thickness through coarse and fine grinding stages. Coarse grinding may rapidly reduce the wafer's thickness using a diamond wheel, while fine grinding may achieve the precise final thickness and a smooth surface. The isolation process may include silicon etching of selectively removing silicon material from a wafer's surface or structure to create through-silicon vias 2303, oxide deposition involving growing a layer of silicon dioxide (SiO₂) on the surface of the wafer 2310 and Chemical Mechanical Polishing (CMP) used for planarization, smoothing, and flattening the surface of the wafer 2310 after multiple layers of materials have been deposited or etched.

FIG. 23D shows Under Bump Metallization (UBM) process. The UBM process may include PVD of a titanium Ti layer, typically around 1000 Angstroms thick, onto the wafer 2310. Photolithography may follow where a pattern is transferred onto the substrate using light-sensitive photoresist materials, defining the layout of the semiconductor components. Next, electroplating may deposit a layer of nickel (Ni) approximately 4 micrometres thick onto the wafer 2310, enhancing conductivity and structural integrity. After the desired patterns are defined, the photoresist layer may be stripped away, exposing the underlying wafer 2310 for further processing. Finally, a seed layer, often including a thin conductive material like copper, may be selectively etched to remove excess material, ensuring precise alignment and connectivity for subsequent layers or components.

FIG. 23E shows de-bonding and die saw process. The de-bonding and die saw process may involve several steps to transform the fabricated dies 2330 into functional electronic components ready for integration into devices. Initially, the fabricated dies 2330 may undergo de-bonding to separate them from the carrier 2302. These individual dies 2330a, 2330b, 2330c may be then carefully mounted onto frames 2304 to provide structural support. Subsequent steps may include cleaning off residual adhesives to ensure pristine surfaces for further processing. Non-conductive film (NCF) lamination may follow, where layers are bonded using specialized techniques like laser grooving and vias (LGV) to facilitate electrical connections and mechanical support. Finally, die sawing may precisely cut the assembled components into individual dies 2330a, 2330b, 2330c, ensuring each is ready for packaging and integration into electronic products.

The following examples pertain to various aspects described herein.

Example 1 is a semiconductor device, including: a second module stacked vertically on a base module, each of the second and base modules comprising: a second tier stacked vertically on a base tier, each of the second and base tiers comprises: a passive die arranged side-by-side laterally with a core die, wherein the passive die comprises a plurality of through-silicon vias (TSVs); and a plurality of bumps disposed on a bottom of the passive die and a bottom of the core die; wherein the core die of the second tier is laterally offset from the core die of the base tier, forming an overhang portion overlapping the passive die of the base tier, and wherein the plurality of bumps couple the overhang portion of the core die of the second tier and the plurality of TSVs of the passive die of the second tier to the plurality of TSVs of the passive die of the base tier and couple a non-overhang portion of the core die of the second tier to the core die of the base tier; wherein the base module further comprises: a bottom redistribution layer (RDL) on which the base tier of the base module is disposed, the bottom RDL coupled to the plurality of bumps of the base tier of the base module; and a top RDL disposed on a top-most tier of the base module; wherein the second module is disposed on the top RDL of the base module, and the top RDL couple the plurality of bumps of the base tier of the second module to a plurality of TSVs of a passive die of the top-most tier of the base module in a one-to-one manner.

In Example 2, the subject matter of Example 1 may optionally further include that the top RDL comprises a routing layer, the routing layer comprising (i) a plurality of top conductive pads coupled to the plurality of bumps of the base tier of the second module in a one-to-one manner, (ii) a plurality of bottom conductive pads coupled to the plurality of TSVs of the passive die of the second tier of the base module in a one-to-one manner, and (iii) a plurality of conductive lines each coupling one of the plurality of top conductive pads to one of the plurality of bottom conductive pads.

In Example 3, the subject matter of Example 2 may optionally further include that the plurality of top conductive pads have a first predetermined size and a first predetermined space between two top conductive pads among the plurality of top conductive pads; the plurality of bottom conductive pads have a second predetermined size and a second predetermined space between two bottom conductive pads among the plurality of bottom conductive pads; and/or the plurality of conductive lines have one of a third predetermined space between two conductive lines among the plurality of conductive lines and a predetermined width.

In Example 4, the subject matter of any one of Examples 1-3 may optionally further include that the second module further comprises (i) a second bottom RDL on which the base tier of the second module is disposed, and (ii) a plurality of module bumps disposed on the second bottom RDL, wherein the second bottom RDL couples the plurality of module bumps to the plurality of bumps of the base tier of the second module in a one-to-one manner; and the top RDL of the base module couples the plurality of module bumps to the plurality of TSVs of the passive die of the top-most tier of the base module in a one-to-one manner.

In Example 5, the subject matter of Example 4 may optionally further include that the core dies, the passive dies and the pluralities of bumps of the second tier and base tier and the second bottom RDL of the second module are identical to the core dies, the passive dies and the pluralities of bumps of the second tier and base tier and the bottom RDL of the base module, respectively.

In Example 6, the subject matter of any one of Examples 1-5 may optionally further include that the second module comprises a second top RDL disposed on a top-most tier of the second module, the semiconductor device further comprising a third module stacked vertically on the second module, wherein the third module comprises: a second tier stacked vertically on a base tier, each of the second and base tiers comprises: a passive die arranged side-by-side laterally with a core die, wherein the passive die of the third module comprises a plurality of TSVs; a plurality of bumps disposed on a bottom of the passive die and a bottom the core die of the middle module; and wherein the core die of the second tier of the third module is laterally offset from the core die of the base tier of the third module, forming an overhang portion overlapping the passive die of the base tier of the third module; the plurality of bumps couple the overhang portion of the core die of the second tier of the third module and the plurality of TSVs of the passive die of the second tier of the third module to the plurality of TSVs of the passive die of the base tier of the third module and couple a non-overhang portion of the core die of the second tier of the third module to the core die of the base tier of the third module; and wherein the third module is disposed on the second top RDL of the second module; the second top RDL of the second module couples the plurality of bumps of the base tier of the third module to the plurality of TSVs of the passive die of the top-most tier of the second module in a one-to-one manner.

In Example 7, the subject matter of any one of Examples 1-6 may optionally further include that each of the second and base modules further comprises a third tier stacked vertically on the second tier, the third tier comprising: a passive die arranged side-by-side laterally with a core die, wherein the passive die of the third tier comprises a plurality of through-silicon vias (TSVs); the core die of the third tier is laterally offset from the core die of the second tier, forming a overhang portion overlapping the passive die of the second tier; and a plurality of bumps disposed on a bottom of the passive die and a bottom of the core die of the third tier; wherein the plurality of bumps couple the overhang portion of the core die of the third tier and the plurality of TSVs of the passive die of the third tier to the plurality of TSVs of the passive die of the second tier and couple a non-overhang portion of the core die of the third tier to the core die of the second tier.

In Example 8, the subject matter of any one of Examples 1-7 may optionally further include that a height of the base module spanning vertically from the bottom RDL to the top RDL is equal to or less than 200 μm.

In Example 9, the subject matter of any one of Examples 1-8 may optionally further include that the plurality of bumps which couple the overhang portion of the core die of the second tier and the plurality of TSVs of the passive die of the second tier to the plurality of TSVs of the passive die of the base tier comprises a first type of bump and the plurality of bumps which couple the non-overhang portion of the core die of the second tier to the core die of the base tier comprises a second type of bump.

In Example 10, the subject matter of Example 9 may optionally further include that the first type of bump has one of (i) a larger diameter, (ii) a greater protrusion height and (iii) a wider pitch than that of the second type of bump.

In Example 11, the subject matter of Example 9 or 10 may optionally further include that each of the first type of bump and the second type of bump includes a pillar and a solider tip extending away from the pillar.

In Example 12, the subject matter of Example 11 may optionally further include that the solder tip of the first type of bump has a higher solder volume than that of the second type of bump.

In Example 13, the subject matter of Example 11 or 12 may optionally further include that the pillar and the solder tip of the first type of bump are made of a same material, and the pillar and the solder tip of the second type of bump are made of different materials.

Example 14 is a semiconductor device, including: a bottom redistribution layer (RDL); a first passive die arranged side-by-side laterally with a first core die in a base tier on the base RDL; and a second passive die arranged side-by-side laterally with a second core die in a second tier stacked vertically on the base tier, wherein the second core die is laterally offset from the first core die, forming an overhang portion overlapping the first passive die; wherein each of the first and second passive dies comprises a plurality of through-silicon vias (TSVs); and wherein the second tier comprises a plurality of bumps disposed on a bottom of the second passive die and a bottom of the second core die, the plurality of bumps comprising a first type of bump configured to couple to the overhang portion of the second core die and the plurality of TSVs of the second passive die to the plurality of TSVs of the first passive die, and a second type of bump configured to couple to a non-overhang portion of the second core die to the first core die.

In Example 15, the subject matter of Example 14 may optionally further include that the first type of bump has one of (i) a larger diameter, (ii) a greater protrusion height and (iii) a wider pitch than that of the second type of bump.

In Example 16, the subject matter of Example 14 or 15 may optionally further include that each of the first type of bump and the second type of bump comprises a pillar and a solder tip extending away from the pillar.

In Example 17, the subject matter of Example 16 may optionally further include that the solder tip of the first type of bump has a higher solder volume than that of the second type of bump.

In Example 18, the subject matter of Example 16 or 17 may optionally further include that the pillar and the solder tip of the first type of bump are made of a same material, and the pillar and the solder tip of the second type of bump are made of different materials.

Example 19 is a method for fabricating a semiconductor device, including: preparing a second module and a base module, wherein preparing each of the second module and the base module comprises: preparing a second tier and a base tier; wherein preparing each of the second tier and the base tier comprises: preparing a core die and a passive die, each of the passive die comprising a plurality of through-silicon vias (TSVs); and disposing a plurality of bumps on a bottom of the passive die and a bottom of the core die; and arranging the passive die side-by-side laterally with the core die; stacking the second tier vertically on the base tier, wherein the stacking the second tier vertically on the base tier comprises: arranging the core die of the second tier such that the core die of the second tier is laterally offset from the core die of the base tier, forming an overhang portion overlapping the passive die of the base tier; coupling the overhang portion of the core die of the second tier and the plurality of TSVs of the passive die of the second tier to the plurality of TSVs of the passive die of the base tier through the plurality of bumps of the second tier of the second module; and coupling an non-overhang portion of the core die of the second tier to the core die of the base tier through the plurality of bumps of the second tier of the second module; wherein preparing the base module further comprises: disposing a bottom redistribution layer (RDL) on a carrier; disposing the base tier on the bottom RDL, coupling the bottom RDL to the plurality of bumps of the base tier of the base module; and disposing a top RDL on a top-most tier of the base module; and stacking the second module vertically on the base module, wherein the stacking the second module vertically on the base module comprises: disposing the second module on the top RDL of the base module such that the top RDL couples the plurality of bumps of the base tier of the second module to a plurality of TSVs of a passive die of the top-most tier of the base module in a one-to-one manner.

In Example 20, the subject matter of Example 19 may optionally further include that the carrier is a glass carrier and the preparing the second module further includes: forming a second bottom RDL; disposing the base tier of the second module on the second bottom RDL; disposing a plurality of module bumps on the second bottom RDL such that the second bottom RDL couples the plurality of modules bumps to the plurality of bumps of the base tier of the second module in a one-to-one manner, and the top RDL of the base module couples the plurality of module bumps to the plurality of TSVs of the passive die of the top-most tier of the base module in a one-to-one manner.

In Example 21, the subject matter of Example 19 may optionally include that the carrier is a glass carrier and the preparing the base module further includes: disposing a plurality of bottom bumps on the bottom RDL; and performing a test on the plurality of bottom bumps to measure an electrical property of the base module.

In Example 22, the subject matter of Example 19 may optionally further include that the carrier is the second module and the stacking of the second module vertically on the base module includes preparing the base module subsequent to preparing the second module.

In Example 23, the subject matter of any one of Examples 18-22 may optionally further include that the preparing the second module further comprises: disposing a second top RDL on a top-most tier of the second module, and further include: preparing a third module, comprising: preparing a second tier and a base tier, wherein preparing each of the second tier and the base tier comprises: preparing a core die and a passive die, each of the passive die comprising a plurality of TSVs; and disposing a plurality of bumps on a bottom of the passive die and a bottom of the core die of the each of the second tier and the base tier of the third module; and arranging the passive die of the each of the second tier and the base tier of the third module side-by-side laterally with the core die of the each of the second tier and the base tier of the third module; stacking the second tier of the third module vertically on the base tier of the third module, wherein the stacking the second tier of the third module vertically on the base tier of the third module comprises: arranging the core die of the second tier of the third module such that the core die of the second tier of the third module is laterally offset from the core die of the base tier of the third module, forming an overhang portion overlapping the passive die of the base tier of the third module; coupling the overhang portion of the core die of the second tier of the third module and the plurality of TSVs of the passive die of the second tier of the third module to the plurality of TSVs of the passive die of the base tier of the third module through the plurality of bumps of the second tier of the third module; and coupling a non-overhang portion of the core die of the second tier of the third module to the core die of the base tier of the third module through the plurality of bumps of the second tier of the third module; stacking the third module vertically on the second module, wherein the stacking the third module vertically on the second module comprises: disposing the third module on the second top RDL of the second module such that the second top RDL of the second module couples the plurality of bumps of the base tier of the third module to a plurality of TSVs of a passive die of the top-most tier of the second module in a one-to-one manner.

In Example 24, the subject matter of any one of Examples 19-23 may optionally further include that preparing each the second module and the base module each further comprises: preparing a third tier, comprising: preparing a core die and a passive die, each of the passive die comprising a plurality of through-silicon vias (TSVs); disposing a plurality of bumps on a bottom of the passive die and a bottom of the core die of the third tier; and arranging the passive die of the third tier side-by-side laterally with the core die of third tier; and stacking the third tier vertically on the second tier, comprising: arranging the core die of the third tier such that the core die of the third tier is laterally offset from the core die of the second tier, forming an overhang portion overlapping the passive die of the second tier; coupling the overhang portion of the core die of the third tier and the plurality of TSVs of the passive die of the third tier to the plurality of TSVs of the passive die of the second tier through the plurality of bumps of the third tier; and coupling the plurality of bumps disposed on a non-overhang portion of the core die of the third tier to the core die of the second tier through the plurality of bumps of the third tier.

In Example 25, the subject matter of any one of Examples 19-24 may optionally further include that a height of the base module spanning vertically from the bottom RDL to the top RDL is equal to or less than 200 μm.

In Example 26, the subject matter of any one of Examples 19-25 may optionally further include that the core dies, the passive dies and the pluralities of bumps of the second tier and base tier and the second bottom RDL of the second module are identical to the core dies, the passive dies and the pluralities of bumps of the second tier and base tier and the bottom RDL of the base module, respectively.

In Example 27, the subject matter of any one of Examples 19-26 may optionally further include that the disposing a plurality of bumps on the bottom of the passive die and the bottom of the core die comprises: disposing a first type of bump under the overhang portion of the core die and the plurality of TSVs of the passive die of the second tier for coupling to the plurality of TSVs of the passive die of the base tier, and a second type of bump under the non-overhang portion of the core die of the second tier for coupling to the core die of the base tier.

In Example 28, the subject matter of Example 27 may optionally include that the first type of bump has one of (i) a larger diameter, (ii) a greater protrusion height and (iii) a wider pitch than that of the second type of bump.

In Example 29, the subject matter of Example 27 or 28 may optionally further include that the disposing each of the first type of bump and the second type of bumps comprises disposing a pillar and a solder tip extending away from the pillar.

In Example 30, the subject matter of Example 29 may optionally further include that the solder tip of the first type of bump has a higher solder volume than that of the second type of bump.

In Example 31, the subject matter of Example 29 or 30 may optionally further include that the pillar and the solder tip of the first type of bump are made of a same material, and the pillar and the solder tip of the second type of bump are made of different materials.

Example 32 is a method for fabricating a semiconductor device, including: preparing a first core die, a first passive die, a second core die and a second passive die, each of the first passive die and the second passive die including a plurality of through-silicon vias (TSVs); disposing a plurality of bumps on a bottom of the second passive die and a bottom of the second core die, the plurality of bumps including a first type of bump disposed on an overhang portion of the second core die and the plurality of TSVs of the passive die configured to couple to the plurality of TSVs of the first passive die, and a second type of bump disposed on a non-overhang portion of the second core die configured to couple to the first core die; arranging the first passive die side-by-side laterally with the first core die on a bottom redistribution layer (RDL) in a base tier; arranging the second passive die side-by-side laterally with the second core die vertically on the base tier in a second tier such that the second core die is laterally offset from the first core die, forming the overhang portion overlapping the first passive die; coupling the overhang portion of the second core die and the plurality of TSVs of the second passive die to the plurality of TSVs of the first passive die through the plurality of bumps of the second core die and the second passive die; and coupling the non-overhang portion of the second core die to the first core die through the plurality of bumps of the second core die and the second passive die.

In Example 33, the subject matter of Example 32 may optionally further include that the first type of bump has one of (i) a larger diameter, (ii) a greater protrusion height and (iii) a wider pitch than that of the second type of bump.

In Example 34, the subject matter of Example 32 or 33 may optionally further include that the disposing each of the first type of bump and the second type of bumps includes disposing a pillar and a solder tip extending away from the pillar.

In Example 35, the subject matter of Example 34 may optionally further include that the solder tip of the first type of bump has a higher solder volume than that of the second type of bump.

In Example 36, the subject matter of Example 34 or 35 may optionally further include that the pillar and the solder tip of the first type of bump are made of a same material, and the pillar and the solder tip of the second type of bump are made of different materials.

While this specification contains many details, these should not be understood as limitations on the scope of what may be claimed, but rather as descriptions of features specific to particular examples. Certain features that are described in this specification or shown in the drawings in the context of separate aspects can also be combined. Conversely, various features that are described or shown in the context of a single aspect can also be implemented in multiple aspects separately or in any suitable sub-combination.

Similarly, while steps/operations of the methods as described above are depicted in a particular order (e.g. as shown in the drawings), this should not be understood as requiring that such operations/steps be performed in the particular order shown or in sequential order, or that all illustrated operations be performed, to achieve desirable results. In certain circumstances, multitasking and parallel processing may be advantageous. For example, some operations/steps may occur in different orders and/or concurrently with other operations/steps apart from those illustrated and/or described herein. In addition, not all illustrated operations/steps may be required to implement one or more aspects or aspects described herein. Also, one or more of the steps depicted herein may be carried out in one or more separate acts and/or phases.

Moreover, the separation/integration of various system components in the aspects described above should not be understood as requiring such separation/integration in all aspects, and it should be understood that the described program components and systems can generally be integrated together in a single product or separated into multiple products.

A number of aspects have been described. Nevertheless, it will be understood that various modifications can be made. Accordingly, other aspects are within the scope of the following claims.

1. A semiconductor device, comprising:
a second module stacked vertically on a base module, each of the second and base modules comprising:
a second tier stacked vertically on a base tier, each of the second and base tiers comprises:
a passive die arranged side-by-side laterally with a core die, wherein the passive die comprises a plurality of through-silicon vias (TSVs); and
a plurality of bumps disposed on a bottom of the passive die and a bottom of the core die;
wherein the core die of the second tier is laterally offset from the core die of the base tier, forming an overhang portion overlapping the passive die of the base tier, and wherein the plurality of bumps couple the overhang portion of the core die of the second tier and the plurality of TSVs of the passive die of the second tier to the plurality of TSVs of the passive die of the base tier and couple a non-overhang portion of the core die of the second tier to the core die of the base tier;
wherein the base module further comprises:
a bottom redistribution layer (RDL) on which the base tier of the base module is disposed, the bottom RDL coupled to the plurality of bumps of the base tier of the base module; and
a top RDL disposed on a top-most tier of the base module;
wherein the second module is disposed on the top RDL of the base module, and the top RDL couples the plurality of bumps of the base tier of the second module to a plurality of TSVs of a passive die of the top-most tier of the base module in a one-to-one manner.

2. The semiconductor device of claim 1, wherein the top RDL comprises a routing layer, the routing layer comprising (i) a plurality of top conductive pads coupled to the plurality of bumps of the base tier of the second module in a one-to-one manner, (ii) a plurality of bottom conductive pads coupled to the plurality of TSVs of the passive die of the second tier of the base module in a one-to-one manner, and (iii) a plurality of conductive lines each coupling one of the plurality of top conductive pads to one of the plurality of bottom conductive pads.

3. The semiconductor device of claim 2, wherein the plurality of top conductive pads have a first predetermined size and a first predetermined space between two top conductive pads among the plurality of top conductive pads; the plurality of bottom conductive pads have a second predetermined size and a second predetermined space between two bottom conductive pads among the plurality of bottom conductive pads; and/or the plurality of conductive lines have one of a third predetermined space between two conductive lines among the plurality of conductive lines and a predetermined width.

4. The semiconductor device of claim 1, wherein the second module further comprises (i) a second bottom RDL on which the base tier of the second module is disposed, and (ii) a plurality of module bumps disposed on the second bottom RDL, wherein the second bottom RDL couples the plurality of module bumps to the plurality of bumps of the base tier of the second module in a one-to-one manner; and the top RDL of the base module couples the plurality of module bumps to the plurality of TSVs of the passive die of the top-most tier of the base module in a one-to-one manner.

5. The semiconductor device of claim 1, wherein the second module comprises a second top RDL disposed on a top-most tier of the second module, the semiconductor device further comprising a third module stacked vertically on the second module, wherein the third module comprises:
a second tier stacked vertically on a base tier, each of the second and base tiers comprises:
a passive die arranged side-by-side laterally with a core die, wherein the passive die of the third module comprises a plurality of TSVs;
a plurality of bumps disposed on a bottom of the passive die and a bottom the core die of the third module; and
wherein the core die of the second tier of the third module is laterally offset from the core die of the base tier of the third module, forming an overhang portion overlapping the passive die of the base tier of the third module; the plurality of bumps couple the overhang portion of the core die of the second tier of the third module and the plurality of TSVs of the passive die of the second tier of the third module to the plurality of TSVs of the passive die of the base tier of the third module and couple a non-overhang portion of the core die of the second tier of the third module to the core die of the base tier of the third module; and
wherein the third module is disposed on the second top RDL of the second module; the second top RDL of the second module couples the plurality of bumps of the base tier of the third module to the plurality of TSVs of the passive die of the top-most tier of the second module in a one-to-one manner.

6. The semiconductor device of claim 1, wherein each of the second and base modules further comprises a third tier stacked vertically on the second tier, the third tier comprising:
a passive die arranged side-by-side laterally with a core die, wherein the passive die of the third tier comprises a plurality of through-silicon vias (TSVs); the core die of the third tier is laterally offset from the core die of the second tier, forming a overhang portion overlapping the passive die of the second tier; and
a plurality of bumps disposed on a bottom of the passive die and a bottom of the core die of the third tier;
wherein the plurality of bumps couple the overhang portion of the core die of the third tier and the plurality of TSVs of the passive die of the third tier to the plurality of TSVs of the passive die of the second tier and couple a non-overhang portion of the core die of the third tier to the core die of the second tier.

7. The semiconductor device of claim 1, wherein the plurality of bumps which couple the overhang portion of the core die of the second tier and the plurality of TSVs of the passive die of the second tier to the plurality of TSVs of the passive die of the base tier comprises a first type of bump and the plurality of bumps which couple the non-overhang portion of the core die of the second tier to the core die of the base tier comprises a second type of bump.

8. The semiconductor device of claim 7, wherein the first type of bump has one of (i) a larger diameter, (ii) a greater protrusion height and (iii) a wider pitch than that of the second type of bump.

9. A semiconductor device, comprising:
a bottom redistribution layer (RDL);
a first passive die arranged side-by-side laterally with a first core die in a base tier on the base RDL; and
a second passive die arranged side-by-side laterally with a second core die in a second tier stacked vertically on the base tier, wherein the second core die is laterally offset from the first core die, forming an overhang portion overlapping the first passive die;
wherein each of the first and second passive dies comprises a plurality of through-silicon vias (TSVs); and
wherein the second tier comprises a plurality of bumps disposed on a bottom of the second passive die and a bottom of the second core die, the plurality of bumps comprising a first type of bump configured to couple to the overhang portion of the second core die and the plurality of TSVs of the second passive die to the plurality of TSVs of the first passive die, and a second type of bump configured to couple to a non-overhang portion of the second core die to the first core die.

10. The semiconductor device of claim 9, wherein the first type of bump has one of (i) a larger diameter, (ii) a greater protrusion height and (iii) a wider pitch than that of the second type of bump.

11. The semiconductor device of claim 9, wherein each of the first type of bump and the second type of bump comprises a pillar and a solder tip extending away from the pillar.

12. The semiconductor device of claim 11, wherein the solder tip of the first type of bump has a higher solder volume than that of the second type of bump.

13. The semiconductor device of claim 11, wherein the pillar and the solder tip of the first type of bump are made of a same material, and the pillar and the solder tip of the second type of bump are made of different materials.

14. A method for fabricating a semiconductor device, comprising:
preparing a second module and a base module, wherein preparing each of the second module and the base module comprises:
preparing a second tier and a base tier; wherein preparing each of the second tier and the base tier comprises:
preparing a core die and a passive die, each of the passive die comprising a plurality of through-silicon vias (TSVs); and
disposing a plurality of bumps on a bottom of the passive die and a bottom of the core die; and
arranging the passive die side-by-side laterally with the core die;
stacking the second tier vertically on the base tier, wherein the stacking the second tier vertically on the base tier comprises:
arranging the core die of the second tier such that the core die of the second tier is laterally offset from the core die of the base tier, forming an overhang portion overlapping the passive die of the base tier;
coupling the overhang portion of the core die of the second tier and the plurality of TSVs of the passive die of the second tier to the plurality of TSVs of the passive die of the base tier through the plurality of bumps of the second tier of the second module; and
coupling an non-overhang portion of the core die of the second tier to the core die of the base tier through the plurality of bumps of the second tier of the second module;
wherein preparing the base module further comprises:
disposing a bottom redistribution layer (RDL) on a carrier;
disposing the base tier on the bottom RDL, coupling the bottom RDL to the plurality of bumps of the base tier of the base module; and
disposing a top RDL on a top-most tier of the base module; and
stacking the second module vertically on the base module, wherein the stacking the second module vertically on the base module comprises:
disposing the second module on the top RDL of the base module such that the top RDL couples the plurality of bumps of the base tier of the second module to a plurality of TSVs of a passive die of the top-most tier of the base module in a one-to-one manner.

15. The method of claim 14, wherein the carrier is a glass carrier and the preparing the second module further comprises:
forming a second bottom RDL;
disposing the base tier of the second module on the second bottom RDL;
disposing a plurality of module bumps on the second bottom RDL such that the second bottom RDL couples the plurality of modules bumps to the plurality of bumps of the base tier of the second module in a one-to-one manner, and the top RDL of the base module couples the plurality of module bumps to the plurality of TSVs of the passive die of the top-most tier of the base module in a one-to-one manner.

16. The method of claim 14, wherein the carrier is a glass carrier and the preparing the base module further comprises:
disposing a plurality of bottom bumps on the bottom RDL; and
performing a test on the plurality of bottom bumps to measure an electrical property of the base module.

17. The method of claim 14, wherein the carrier is the second module, and the stacking of the second module vertically on the base module comprises preparing the base module subsequent to preparing the second module.

18. The method of claim 14, wherein the preparing the second module further comprises:
disposing a second top RDL on a top-most tier of the second module, the method further comprising:
preparing a third module, comprising:
preparing a second tier and a base tier, wherein preparing each of the second tier and the base tier comprises:
preparing a core die and a passive die, each of the passive die comprising a plurality of TSVs; and
disposing a plurality of bumps on a bottom of the passive die and a bottom of the core die of the each of the second tier and the base tier of the third module; and
arranging the passive die of the each of the second tier and the base tier of the third module side-by-side laterally with the core die of each of the second tier and the base tier of the third module;
stacking the second tier of the third module vertically on the base tier of the third module, wherein the stacking the second tier of the third module vertically on the base tier of the third module comprises:
arranging the core die of the second tier of the third module such that the core die of the second tier of the third module is laterally offset from the core die of the base tier of the third module, forming an overhang portion overlapping the passive die of the base tier of the third module;
coupling the overhang portion of the core die of the second tier of the third module and the plurality of TSVs of the passive die of the second tier of the third module to the plurality of TSVs of the passive die of the base tier of the third module through the plurality of bumps of the second tier of the third module; and
coupling a non-overhang portion of the core die of the second tier of the third module to the core die of the base tier of the third module through the plurality of bumps of the second tier of the third module;
stacking the third module vertically on the second module, wherein the stacking the third module vertically on the second module comprises:
disposing the third module on the second top RDL of the second module such that the second top RDL of the second module couples the plurality of bumps of the base tier of the third module to a plurality of TSVs of a passive die of the top-most tier of the second module in a one-to-one manner.

19. The method of claim 14, wherein preparing each the second module and the base module further comprises:
preparing a third tier, comprising:
preparing a core die and a passive die, each of the passive die comprising a plurality of through-silicon vias (TSVs);
disposing a plurality of bumps on a bottom of the passive die and a bottom of the core die of the third tier; and
arranging the passive die of the third tier side-by-side laterally with the core die of third tier; and
stacking the third tier vertically on the second tier, comprising:
arranging the core die of the third tier such that the core die of the third tier is laterally offset from the core die of the second tier, forming an overhang portion overlapping the passive die of the second tier;
coupling the overhang portion of the core die of the third tier and the plurality of TSVs of the passive die of the third tier to the plurality of TSVs of the passive die of the second tier through the plurality of bumps of the third tier; and
coupling a non-overhang portion of the core die of the third tier to the core die of the second tier through the plurality of bumps of the third tier.

20. The method of claim 14, wherein the disposing a plurality of bumps on the bottom of the passive die and the bottom of the core die comprises:
disposing a first type of bump under the overhang portion of the core die and the plurality of TSVs of the passive die of the second tier for coupling to the plurality of TSVs of the passive die of the base tier, and a second type of bump under the non-overhang portion of the core die of the second tier for coupling to the core die of the base tier.
